(19) United States
(12) Patent Application Publication
(10) Pub. No.: US 2016/0276183 A1
(43) Pub. Date: Sep. 22, 2016

(54) Substrate Processing Apparatus

(71) Applicant: Hitachi Kokusai Electric Inc., Tokyo (JP)

(72) Inventors: Naofumi OHASHI, Toyama (JP); Kazuyuki TOYODA, Toyama (JP); Shun MATSUI, Toyama (JP)

(21) Appl. No.: 15/054,768

(22) Filed: Feb. 26, 2016

(30) Foreign Application Priority Data
Mar. 20, 2015 (JP) 2015-058326

(51) Int. Cl. H01L 21/67

(52) U.S. Cl. CPC H01L 21/67069

(57) ABSTRACT

A technique partially adjusts a plasma distribution in a processing region in order to suppress the reduction in in-plane uniformity of a film formed on a substrate. Provided is a substrate processing apparatus including: a substrate support configured to support a substrate; a dividing structure defining a processing region in a space facing the substrate support; a gas supply unit configured to supply a processing gas into the processing region; and a plasma generating unit configured to generate an active species by plasmatizing the processing gas supplied into the processing region by the gas supply unit, and to control an activity of the active species independently for each portion of the processing region when plasmatizing the processing gas.

### CROSS REFERENCE TO RELATED APPLICATIONS

This application claims foreign priority under 35 U.S.C. §119(a)-(d) to Application No. JP 2015-058326 filed on Mar. 20, 2015, the entire contents of which are hereby incorporated by reference.

### FIELD OF THE INVENTION

The present invention relates to a substrate processing apparatus and a plasma generator, which are used in a method of manufacturing a semiconductor device.

### BACKGROUND

In a method of manufacturing a semiconductor device, various types of process processing are performed on a substrate such as a wafer and the like. Among the various types of process processing, for example, there is film forming processing using an alternate supply method. The alternate supply method is a method in which a source gas and at least two types of processing gases serving as reaction gases that react with the source gas are alternately supplied onto the substrate which is a processing target, an adsorption layer is formed by reacting with the processing gases on a surface of the substrate, and a film having a desired film thickness is formed by stacking the layer.

An embodiment of a substrate processing apparatus for performing a film forming process using the alternate supply method has the following configuration. That is, in the substrate processing apparatus of the embodiment, a space having a circular shape in a plan view is divided into a plurality of processing regions, and different types of gases are respectively supplied into the processing regions. The film forming process of the substrate is performed by rotating and moving a substrate support placed on the substrate such that the substrate which is a processing target sequentially passes through the processing regions. Also, in the processing regions into which the processing gas is supplied, in order to increase the reaction efficiency of the source gas, the substrate processing apparatus of the embodiment is configured to plasmatize the reaction gas (e.g., see Japanese Laid-open Patent Application No. 2013-84898).

In the substrate processing apparatus having the above-described configuration, when the variation of a plasma distribution occurs in the processing region into which the plasmatized reaction gas is supplied, it causes the reduction in in-plane uniformity such as the film thickness, the film quality or the like of a film formed on the substrate.

### SUMMARY

It is an object of the present invention to provide a technique capable of partially adjusting a plasma distribution of a processing region in order to suppress the degradation of in-plane uniformity of a film formed on a substrate.

According to an aspect of the present invention, there is provided a technique including: a substrate support configured to support a substrate; a dividing structure defining a processing region in a space facing the substrate support; a gas supply unit configured to supply a processing gas into the processing region; and a plasma generating unit configured to generate an active species by plasmatizing the processing gas supplied into the processing region by the gas supply unit, and to control an activity of the active species independently for each portion of the processing region when plasmatizing the processing gas.

### BRIEF DESCRIPTION OF THE DRAWINGS

FIG. 1 is a cross-sectional schematic view of a cluster type substrate processing apparatus according to a first embodiment of the present invention.

FIG. 2 is an explanatory diagram schematically illustrating an example of a configuration of a reaction container included in the substrate processing apparatus according to the first embodiment of the present invention.

FIGS. 3A through 3D are explanatory diagrams illustrating an example of a configuration of a gas supply plate included in the substrate processing apparatus according to the first embodiment of the present invention, where FIG. 3A is a conceptual view illustrating regions in a processing space in a plan view, FIG. 3B is a side sectional view taken along line C-C of FIG. 3A, FIG. 3C is a side sectional view taken along line D-D of FIG. 3A, and FIG. 3D is a side sectional view taken along line E-E of FIG. 3A.

FIG. 4 is a conceptual view schematically illustrating an example of a configuration of a gas inlet shaft and gas pipes included in the substrate processing apparatus according to the first embodiment of the present invention.

FIG. 5 is a block diagram schematically illustrating an example of a configuration of a controller included in the substrate processing apparatus according to the first embodiment of the present invention.

FIG. 6 is a flowchart illustrating a substrate processing process according to an embodiment of the present invention.

FIG. 7 is a flowchart illustrating a relative position movement processing operation performed in a film forming process of FIG. 6 in detail.

FIG. 8 is a flowchart illustrating a gas supply and exhaust processing operation performed in the film forming process of FIG. 6 in detail.

FIG. 9 is an explanatory diagram schematically illustrating an overview of a plasma generating unit included in the substrate processing apparatus according to the first embodiment of the present invention.

FIGS. 10A and 10B are explanatory diagrams illustrating an example of a configuration of the plasma generating unit included in the substrate processing apparatus according to the first embodiment of the present invention, where FIG. 10A is a plan view schematically illustrating main components of the plasma generating unit, and FIG. 10B is a side sectional view schematically illustrating the main components thereof.

FIG. 11 is an explanatory diagram illustrating the example of the configuration of the plasma generating unit included in the substrate processing apparatus according to the first embodiment of the present invention, and is a perspective view schematically illustrating the main components of the plasma generating unit.

FIGS. 12A and 12B are explanatory diagrams illustrating another example of the configuration of the plasma generating unit included in the substrate processing apparatus according to the first embodiment of the present invention, where FIG. 12A is a plan view schematically illustrating main components of the plasma generating unit, and FIG. 12B is a side sectional view schematically illustrating the main components thereof.

FIG. 13 is an explanatory diagram illustrating another example of the configuration of the plasma generating unit included in the substrate processing apparatus according to the first embodiment of the present invention, and is a plan view schematically illustrating the main components of the plasma generating unit.

FIG. 14 is an explanatory diagram illustrating a modification of still another example of the configuration of the plasma generating unit included in the substrate processing apparatus according to the first embodiment of the present invention, and is a plan view schematically illustrating the main components of the plasma generating unit.

FIG. 15 is an explanatory diagram illustrating an example of a configuration of a plasma generating unit included in a substrate processing apparatus according to a second embodiment of the present invention, and is a side sectional view schematically illustrating main components of the plasma generating unit.

FIG. 16 is an explanatory diagram illustrating an example of a configuration of a plasma generating unit included in a substrate processing apparatus according to a third embodiment of the present invention, and is a plan view schematically illustrating main components of the plasma generating unit.

FIGS. 17A and 17B are explanatory diagrams illustrating an example of a configuration of a plasma generating unit included in a substrate processing apparatus according to a fourth embodiment of the present invention, where FIG. 17A is a plan view schematically illustrating main components of the plasma generating unit, and FIG. 17B is a conceptual view schematically illustrating the main components thereof.

FIGS. 18A and 18B are explanatory diagrams illustrating a specific example of a film forming process performed on a substrate processing apparatus according to a fifth embodiment of the present invention, where FIG. 18A is a plan view illustrating an example of a film thickness distribution of a Poly-Si film, and FIG. 18B is a plan view illustrating an example of a film thickness distribution of a SiN film.

FIGS. 19A and 19B are explanatory diagrams illustrating examples of a division form of a processing region in a substrate processing apparatus according to another embodiment of the present invention, where FIG. 19A is a plan view illustrating a specific example of the division form, and FIG. 19B is a plan view illustrating another specific example thereof.

FIGS. 20A and 20B are explanatory diagrams illustrating examples of a division form of a processing region in a substrate processing apparatus according to still another embodiment of the present invention, where FIG. 20A is a plan view illustrating a specific example of the division form, and FIG. 20B is a plan view illustrating another specific example thereof.

### DETAILED DESCRIPTION

### First Embodiment of the Present Invention

Hereinafter, a first embodiment of the present invention will be described with reference to the drawings.

### (1) Configuration of Substrate Processing Apparatus

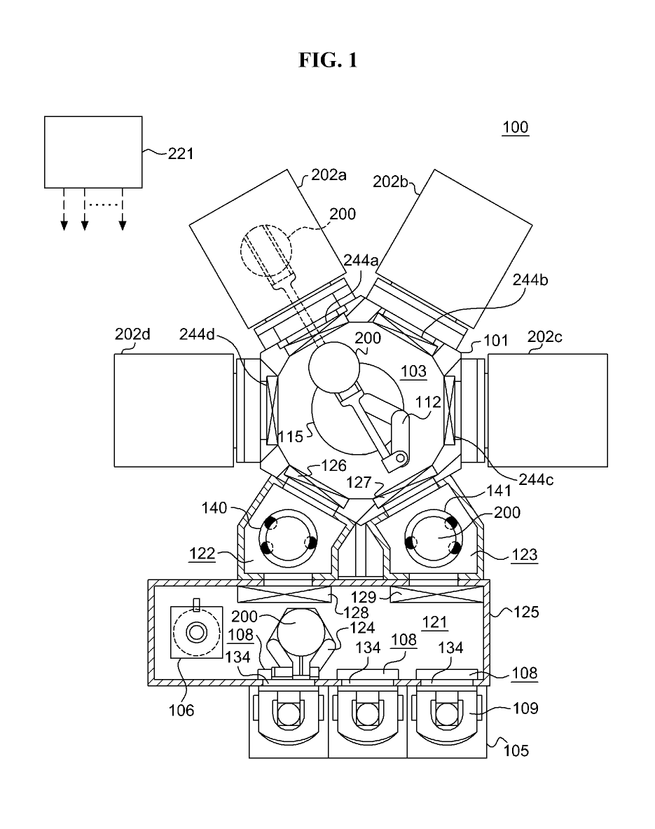

FIG. 1 is a cross-sectional view of a cluster type substrate processing apparatus according to the first embodiment. Also, in the substrate processing apparatus to which the present invention is applied, as a carrier for transferring a wafer 200 serving as a substrate, a front opening unified pod (FOUP) (hereinafter, referred to as a “pod”) is used. A transfer device of the cluster type substrate processing apparatus according to the present embodiment is divided into a vacuum side and an atmosphere side. The term “vacuum” used in this specification refers to an industrial vacuum. Also, for convenience of description, a direction from a vacuum transfer chamber 103 of FIG. 1 toward an atmosphere transfer chamber 108 is referred to as a front side.

### (Configuration of Vacuum Side)

A cluster type substrate processing apparatus 100 includes the vacuum transfer chamber 103 serving as a first transfer chamber having a load lock chamber structure in which a pressure therein can be reduced to a pressure (e.g., 100 Pa) below atmospheric pressure such as a vacuum state. A housing 101 of the vacuum transfer chamber 103 has, for example, a hexagonal shape in a plan view, and a box shape of which both upper and lower ends are closed.

At two side walls located on the front side among six side walls constituting the housing 101 of the vacuum transfer chamber 103, load lock chambers 122 and 123 are respectively installed to be in communication with the vacuum transfer chamber 103 through gate valves 126 and 127.

At two side walls among the other four side walls of the vacuum transfer chamber 103, process chambers 202a and 202b are respectively installed to be in communication with the vacuum transfer chamber 103 through gate valves 244a and 244b. A processing gas supply system, an inert gas supply system, an exhaust system and the like to be described below are installed in the process chambers 202a and 202b. In the process chambers 202a and 202b, as will be described below, a plurality of processing regions and the same number of purge regions as the processing regions are alternately arranged in a single reaction container. By rotating a susceptor serving as a substrate support installed in the reaction container, the process chambers 202a and 202b are configured such that the wafer 200 which is the substrate alternately passes through the processing region and the purge region. According to such a configuration, a processing gas and an inert gas are alternately supplied onto the wafer 200, and the following substrate processing is performed. Specifically, a variety of substrate processing such as a processing for forming a thin film on the wafer 200, a processing for oxidizing, nitriding, carbonizing or the like a surface of the wafer 200, a processing for etching the surface of the wafer 200 or the like are performed.

At the two remaining side walls of the vacuum transfer chamber 103, cooling chambers 202c and 202d are respectively installed to be in communication with the vacuum transfer chamber 103 through gate valves 244c and 244d.

A vacuum transfer robot 112 serving as a first transfer mechanism is installed in the vacuum transfer chamber 103. The vacuum transfer robot 112 is configured to simultaneously transfer, for example, two wafers 200 (illustrated as a dotted line in FIG. 1) between the load lock chambers 122 and 123 and the process chambers 202a and 202b, and between the load lock chambers 122 and 123 and the cooling chambers 202c and 202d. The vacuum transfer robot 112 is configured to perform lifting by an elevator 115 while maintaining airtightness of the vacuum transfer chamber 103. Also, a wafer detecting sensor (not illustrated) which detects whether the wafer 200 is present or not is installed in the vicinity of each of the gate valves 126 and 127 of the load lock chambers 122 and 123, the gate valves 244a and 244b of the process chambers 202a and 202b and the gate valves 244c and 244d of the cooling chambers 202c and 202d. The wafer detecting sensor is referred to as a substrate detecting unit.

Each of the load lock chambers 122 and 123 is configured to have a load lock chamber structure in which a pressure therein can be reduced to a pressure (a negative pressure) below atmospheric pressure such as a vacuum state. That is, at front sides of the load lock chambers 122 and 123, an atmosphere transfer chamber 121 serving as a second transfer chamber to be described below is installed with gate valves 128 and 129 therebetween. Accordingly, after the gate valves 126-129 are closed and the insides of the load lock chambers 122 and 123 are vacuum-exhausted, the wafer 200 may be transferred between the load lock chambers 122 and 123 and the vacuum transfer chamber 103 while maintaining a vacuum state of the vacuum transfer chamber 103 by opening the gate valves 126 and 127. Also, each of the load lock chambers 122 and 123 serves as a spare chamber which temporarily accommodates the wafer 200 loaded into the vacuum transfer chamber 103. In this case, in the load lock chamber 122, the wafer 200 is placed on a substrate support 140, and in the load lock chamber 123, the wafer 200 is placed on a substrate support 141.

### (Configuration of Atmosphere Side)

The atmosphere transfer chamber 121 serving as the second transfer chamber used under substantially atmospheric pressure is installed at the atmosphere side of the substrate processing apparatus 100. That is, the atmosphere transfer chamber 121 is installed at the front sides of the load lock chambers 122 and 123 [i.e., sides opposite to the vacuum transfer chamber 103] with the gate valves 128 and 129 therebetween. Also, the atmosphere transfer chamber 121 is installed to be in communication with the load lock chambers 122 and 123.

An atmosphere transfer robot 124 serving as a second transfer mechanism which transfers the wafer 200 is installed in the atmosphere transfer chamber 121. The atmosphere transfer robot 124 is configured to perform lifting by an elevator (not illustrated) installed in the atmosphere transfer chamber 121, and to perform laterally reciprocating movement by a linear actuator (not illustrated). Also, a wafer detecting sensor (not illustrated) which detects whether the wafer 200 is present or not is installed in the vicinity of each of the gate valves 128 and 129 of the atmosphere transfer chamber 121. The wafer detecting sensor is referred to as a substrate detecting unit.

Also, a notch aligning device 106 serving as a device for correcting a position of the wafer 200 is installed in the atmosphere transfer chamber 121. The notch aligning device 106 determines a crystal orientation or a position alignment or the like of the wafer 200 by a notch of the wafer 200, and corrects the position of the wafer 200 based on the determined information. Also, an orientation flat aligning device (not illustrated) instead of the notch aligning device 106 may be installed. A clean unit (not illustrated) which supplies clean air is installed above the atmosphere transfer chamber 121.

At a front side of the housing 125 of the atmosphere transfer chamber 121, substrate transfer ports 134 which load or unload the wafer 200 into or from the atmosphere transfer chamber 121 and pod openers 108 are installed. At sides opposite to the pod openers 108, that is, at an outer side of the housing 125, load ports (I/O stage) 105 are installed with the substrate transfer ports 134 therebetween. Pods 109 which accommodate the plurality of wafers 200 are placed on the load port 105. Also, a cover 135 which opens or closes the substrate transfer port 134, an opening and closing mechanism 143 which opens or closes a cap of the pod 109, and an opening and closing mechanism driving unit 136 which drives the opening and closing mechanism 143 are installed in the atmosphere transfer chamber 121. The pod opener 108 may load or unload the wafer 200 into or from the pod 109 by opening or closing the cap of the pod 109 placed on the load port 105. Also, the pod 109 is configured to perform loading (supplying) into and unloading (discharging) from the load port 105 by a transfer device (such as an RGV) (not illustrated).

The transfer device of the substrate processing apparatus 100 according to the present embodiment mainly includes the vacuum transfer chamber 103, the load lock chambers 122 and 123, the atmosphere transfer chamber 121 and the gate valves 126-129.

Also, a controller 221 serving as a control unit to be described below is electrically connected to respective units constituting the transfer device of the substrate processing apparatus 100. The controller 221 is configured to control operations of the above-described respective units.

### (Wafer Transfer Operation)

Next, an operation for transferring the wafer 200 in the substrate processing apparatus 100 according to the first embodiment will be described. Also, the operations of respective units constituting the transfer device of the substrate processing apparatus 100 are controlled by the controller 221.

First, the pod 109 which accommodates, for example, 25 unprocessed wafers 200, is loaded into the substrate processing apparatus 100 by the transfer device (not illustrated). The loaded pod 109 is placed on the load port 105. The opening and closing mechanism 143 opens the substrate transfer port 134 and a wafer loading and unloading opening of the pod 109 by removing the cover 135 and the cap of the pod 109.

When the wafer loading and unloading opening of the pod 109 is open, the atmosphere transfer robot 124 installed in the atmosphere transfer chamber 121 picks up one wafer 200 from the pod 109 to place on the notch aligning device 106.

The notch aligning device 106 adjusts a notch position of the wafer 200 and the like by moving the placed wafer 200 in a horizontal direction and a vertical direction (an X direction and a Y direction) and in a circumferential direction. While the notch aligning device 106 adjusts a position of the first wafer 200, the atmosphere transfer robot 124 picks up a second wafer 200 from the pod 109 to load the second wafer 200 into the atmosphere transfer chamber 121 and to stand by in the atmosphere transfer chamber 121.

After the adjustment of the position of the first wafer 200 is completed by the notch aligning device 106, the atmosphere transfer robot 124 picks up the first wafer 200 placed on the notch aligning device 106. The atmosphere transfer robot 124 places the second wafer 200, which is held by the atmosphere transfer robot 124 at that time, on the notch aligning device 106. Then, the notch aligning device 106 adjusts a notch position of the placed second wafer 200 and the like.

Next, the gate valve 128 is opened, and the atmosphere transfer robot 124 loads the first wafer 200 into the load lock chamber 122 to place on the substrate support 140. During this transferring operation, the gate valve 126 at the vacuum transfer chamber 103 side is closed, and a reduced-pressure atmosphere in the vacuum transfer chamber 103 is maintained. When the transfer of the first wafer 200 onto the substrate support 140 is completed, the gate valve 128 is closed, and the inside of the load lock chamber 122 is exhausted so as to be a negative pressure by an exhaust device (not illustrated).

Then, the atmosphere transfer robot 124 repeats the above-described operations. However, when the load lock chamber 122 is in a negative pressure state, the atmosphere transfer robot 124 does not load the wafer 200 into the load lock chamber 122, and stops and stands by at a position right in front of the load lock chamber 122.

When a pressure in the load lock chamber 122 is reduced to a preset pressure value (e.g., 100 Pa), the gate valve 126 is opened, and the load lock chamber 122 communicates with the vacuum transfer chamber 103. Next, the vacuum transfer robot 112 disposed in the vacuum transfer chamber 103 picks up the first wafer 200 from the substrate support 140 to load into the vacuum transfer chamber 103.

After the vacuum transfer robot 112 picks up the first wafer 200 from the substrate support 140, the gate valve 126 is closed, the pressure in the load lock chamber 122 is restored to the atmospheric pressure, and the preparation for loading next wafer into the load lock chamber 122 is performed. At the same time, the gate valve 244a of the process chamber 202a with a predetermined pressure (e.g., 100 Pa) is opened, and the vacuum transfer robot 112 loads the first wafer 200 into the process chamber 202a. This operation is repeated until an arbitrary number (e.g., five) of wafers 200 are loaded into the process chamber 202a. When the arbitrary number (e.g., five) of wafers 200 are loaded into the process chamber 202a, the gate valve 244a is closed. A processing gas is supplied from a gas supply unit to be described below into the process chamber 202a, and a predetermined processing is performed on the wafer 200.

When the predetermined processing is completed in the process chamber 202a and the cooling of the wafer 200 is completed in the process chamber 202a as will be described below, the gate valve 244a is opened. Then, the processed wafer 200 is unloaded from the inside of the process chamber 202a into the vacuum transfer chamber 103 by the vacuum transfer robot 112. After the wafer 200 is unloaded, the gate valve 244a is closed.

Next, the gate valve 127 is opened, and the wafer 200 unloaded from the process chamber 202a is loaded into the load lock chamber 123 to be placed on the substrate support 141. Also, a pressure in the load lock chamber 123 is reduced to a preset pressure value by the exhaust device (not illustrated). Then, the gate valve 127 is closed, an inert gas is introduced through an inert gas supply unit (not illustrated) connected to the load lock chamber 123, and the pressure in the load lock chamber 123 is restored to the atmospheric pressure.

When the pressure in the load lock chamber 123 is restored to the atmospheric pressure, the gate valve 129 is opened. Next, after the atmosphere transfer robot 124 picks up the processed wafer 200 from the substrate support 141 to unload into the atmosphere transfer chamber 121, the gate valve 129 is closed. Then, the processed wafer 200 is accommodated in the pod 109 through the substrate transfer port 134 of the atmosphere transfer chamber 121 by the atmosphere transfer robot 124. Here, the cap of the pod 109 may be maintained open until a maximum of 25 wafers 200 are loaded therein. Also, the processed wafer 200 is not accommodated in the empty pod 109, and may be accommodated in the pod 109 from which the wafer has been unloaded.

When the predetermined processing is performed on all the wafers 200 in the pod 109 by the above-described process and all the 25 processed wafers 200 are accommodated in a predetermined pod 109, the cap of the pod 109 and the cover 135 of the substrate transfer port 134 are closed by the opening and closing mechanism 143. Then, the pod 109 is transferred from the load port 105 to the next process by the transfer device (not illustrated). The wafers 200 are sequentially processed in a batch of 25 wafers by repeating the above-described operations.

### (2) Configuration of Process Chamber

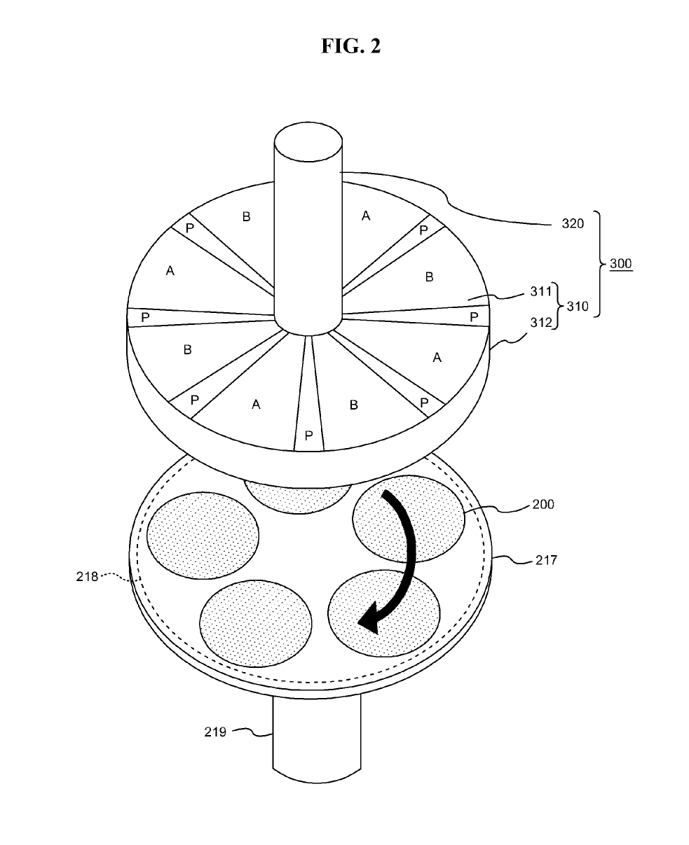

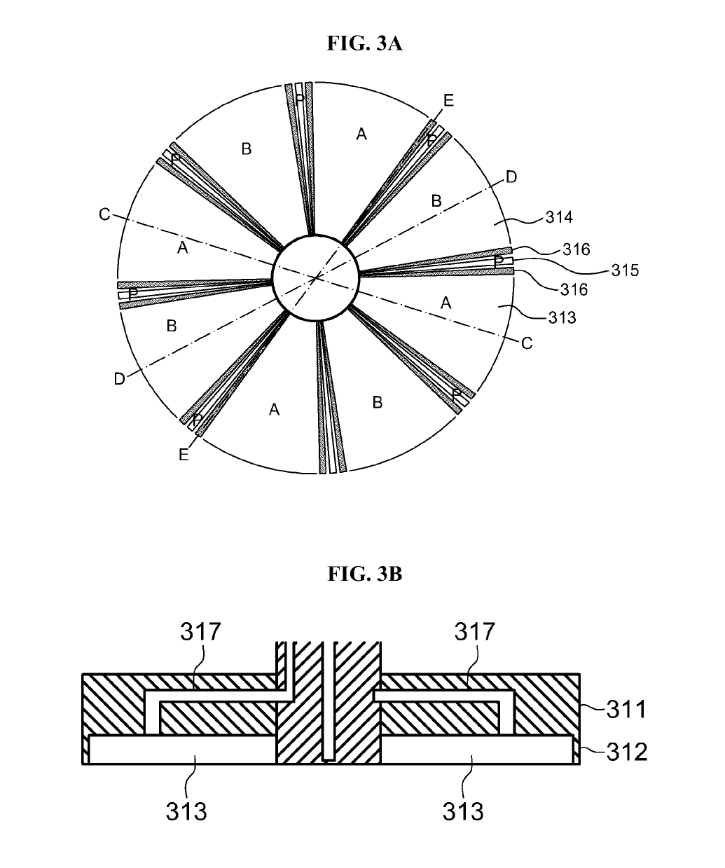

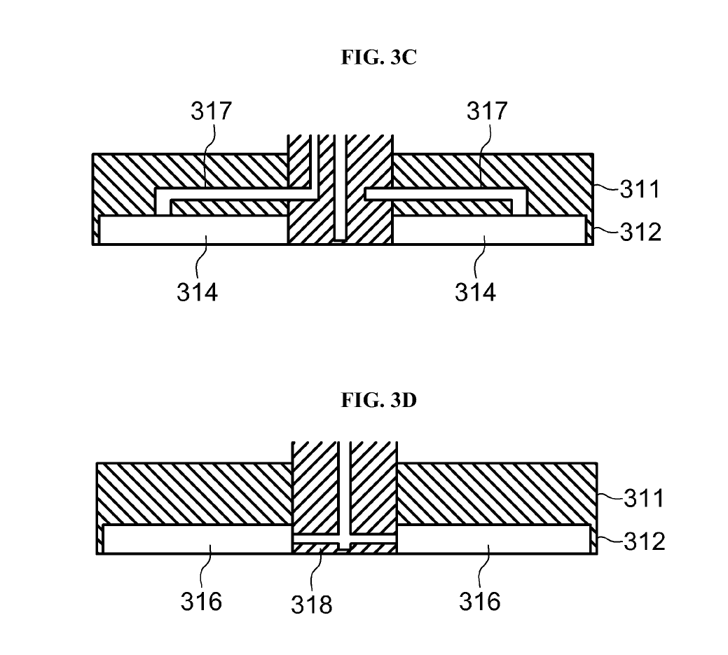

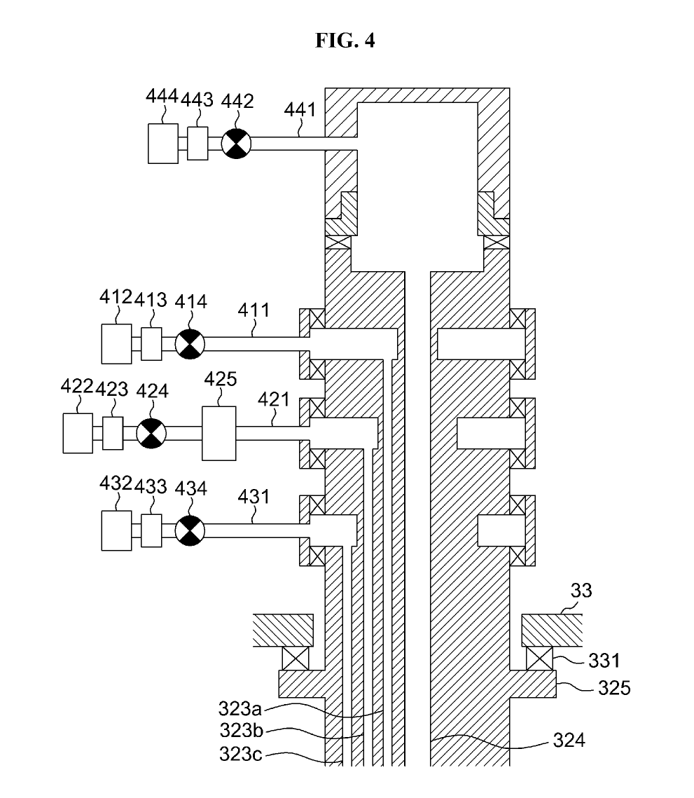

Next, a configuration of the process chamber 202a serving as a processing furnace according to the first embodiment will be generally described with reference to FIGS. 2 through 4. FIG. 2 is an explanatory diagram schematically illustrating an example of a configuration of the reaction container included in the substrate processing apparatus according to the first embodiment. FIGS. 3A through 3D are explanatory diagrams illustrating an example of a configuration of a gas supply plate included in the substrate processing apparatus according to the first embodiment. FIG. 4 is a conceptual view schematically illustrating an example of a configuration of a gas inlet shaft and gas pipes included in the substrate processing apparatus according to the first embodiment. Also, since the process chamber 202b has the same configuration as the process chamber 202a, description thereof is omitted.

### (Reaction Container)

The substrate processing apparatus described in the first embodiment includes the reaction container (not illustrated). The reaction container is configured, for example, as a closed container made of a metal material such as aluminum (Al), stainless steel (SUS) or the like. Also, a substrate loading and unloading port (not illustrated) is installed at a side surface of the reaction container, and the wafer 200 is transferred through the substrate loading and unloading port. Also, a gas exhaust system (not illustrated) such as a vacuum pump, a pressure controller or the like is connected to the reaction container, and a pressure in the reaction container may be adjusted to a predetermined pressure using the gas exhaust system.

### (Substrate Placement Unit)

As illustrated in FIG. 2, a susceptor 217 serving as a substrate support on which the wafer 200 is placed is installed inside of the reaction container. The susceptor 217 is formed, for example, in a disk shape, and is configured such that the plurality of wafers 200 are placed on an upper surface thereof (a substrate placement surface) in a circumferential direction at equal intervals. Also, a substrate placement unit 10 includes a heater 218 serving as a heat source, and is configured such that a temperature of the wafer 200 is maintained to a predetermined temperature (e.g., from room temperature to about 1,000° C.) using the heater 218. Also, a temperature sensor (not illustrated) is installed in the susceptor 217. Also, although the case in which five wafers 200 are placed therein is illustrated in the drawing, the present invention is not limited thereto and the number of placed wafers may be appropriately set. For example, as the number of placed wafers is increased, processing throughput may be expected to improve, and as the number of placed wafers is decreased, the enlargement of the susceptor 217 may be suppressed. Since the substrate placement surface of the susceptor 217 is directly in contact with the wafer 200, the substrate placement surface is preferably formed of, for example, a material such as quartz, alumina or the like. Also, a concave portion (not illustrated) having a circular shape may be installed on the substrate placement surface of the susceptor 217. A diameter of the concave portion is preferably slightly greater than that of the wafer 200. The positioning of the wafer 200 may be easily performed by placing the wafer 200 in the concave portion. Also, although centrifugal force is generated in the wafer 200 when the susceptor rotates, a position deviation of the wafer 200 due to the centrifugal force may be prevented by placing the wafer 200 in the concave portion.

The susceptor 217 is configured such that the plurality of wafers 200 are rotatable in a state of supporting the plurality of wafers 200. Specifically, the susceptor 217 is connected to a rotating and driving mechanism 219 of which a rotary shaft is in the vicinity of the center of a disk, and is configured to be rotated and driven by the rotating and driving mechanism 219. The rotating and driving mechanism 219 may be configured to include, for example, a rotational bearing for supporting the susceptor 217 to be rotatable, a drive source represented by an electric motor and the like. Also, here, although the case in which the susceptor 217 is configured to be rotatable is described as an example, a cartridge head 300 may be configured to be rotatable when a relative position of the wafer 200 placed on the susceptor 217 and the cartridge head 300 to be described below can be changed. When the susceptor 217 is configured to be rotatable, the configuration complexity of gas pipes to be described below may be suppressed unlike the case in which the cartridge head 300 is rotated. On the other hand, when the cartridge head 300 is rotated, the inertia moment acting on the wafer 200 may be suppressed compared to the case in which the susceptor 217 is rotated, and thus a rotational velocity thereof may be increased.

### (Cartridge Head)

Also, the cartridge head 300 is installed above the susceptor 217 in the reaction container. The cartridge head 300 is configured to supply various gases (a source gas, a reaction gas or a purge gas) onto the wafer 200 placed on the susceptor 217 from an upper side thereof, and to exhaust the supplied various gases to the upper side thereof.

In order to perform the supply and exhaust of various gases to the upper side thereof, the cartridge head 300 includes a gas supply plate 310 formed in a circular shape in a plan view corresponding to the susceptor 217 and a gas inlet shaft 320 which passes through the reaction container and extends from the gas supply plate 310 to the outside of the container. Also, both the gas supply plate 310 and the gas inlet shaft 320 constituting the cartridge head 300 are formed of, for example, a metal material such as Al, SUS or the like or a ceramic material such as quartz, alumina or the like.

### (Gas Supply Plate)

The gas supply plate 310 is used to supply various gases into a processing space formed on the susceptor 217. Therefore, the gas supply plate 310 includes a processing space top plate portion 311 having a disk shape facing the susceptor 217 and an outer cylindrical portion 312 having a cylindrical shape which extends from an outer peripheral edge portion of the processing space top plate portion 311 toward the susceptor 217. A processing space for performing the processing of the wafer 200 placed on the susceptor 217 is formed between the processing space top plate portion 311 surrounded by the outer cylindrical portion 312 and the susceptor 217 so as to face the susceptor 217.

The processing space formed on the susceptor 217 by the gas supply plate 310 is divided into a plurality of processing regions and inert gas supply regions (see the marks A, B and P in the drawing). Specifically, as illustrated in FIG. 3A, the processing space includes each of, for example, two or more (specifically, four) of source gas supply regions 313 (see the mark A in the drawing) and reaction gas supply regions 314 (see the mark B in the drawing) serving as a plurality of processing regions and inert gas supply regions 315 (see the mark P in the drawing) interposed between the source gas supply regions 313 and the reaction gas supply regions 314. As will be described below, the source gas supply region 313 becomes a source gas atmosphere by supplying a source gas, which is one of the processing gases, into the source gas supply region 313. The reaction gas supply region 314 becomes a reaction gas atmosphere by supplying a reaction gas, which is one of the processing gases, into the reaction gas supply region 314. Also, when the reaction gas is plasmatized and supplied into the reaction gas supply region 314, the inside of the reaction gas supply region 314 becomes a plasmatized reaction gas atmosphere or an activated reaction gas atmosphere. The inert gas supply region 315 becomes an inert gas atmosphere by supplying an inert gas serving as a purge gas into the inert gas supply region 315. In such a divided processing space, a predetermined processing is performed on the wafer 200 according to the gases respectively supplied into the regions 313 through 315.

Also, a dividing structure for dividing the processing space into the regions 313 through 315 is installed in the processing space formed by the gas supply plate 310. For example, exhaust regions 316 disposed to extend from an inner peripheral side of the processing space top plate portion 311 toward an outer peripheral side thereof in a radial direction are installed between the regions 313 through 315. As will be described below, the exhaust regions 316 are connected to an exhaust pipe 318. Also, the exhaust region 316 may include a boundary plate serving as a dividing structure. The boundary plate is installed to extend from the processing space top plate portion 311 toward the susceptor 217, and is disposed close to the susceptor 217 such that a lower end thereof does not interfere with the wafer 200 placed on the susceptor 217. Accordingly, an amount of the gas passing between the boundary plate and the susceptor 217 is reduced, and thus the mixing of the gas between the regions 313 through 315 is suppressed. Also, the dividing structure may be any structure that can change a space volume of an upper side of the wafer 200 instead of the boundary plate as long as it can divide the regions 313 through 315. For example, when a distance between the wafer 200 and the processing space top plate portion 311 in the inert gas supply region 315 is smaller than that in the source gas supply region 313 and a distance between the wafer 200 and the processing space top plate portion 311 in the inert gas supply region 315 is smaller than that in the reaction gas supply region 314, a space volume of the inert gas supply region 315 may be smaller than that of the source gas supply region 313 or the reaction gas supply region 314. Even in this case, the introduction of the source gas and the reaction gas into the inert gas supply region 315 may be suppressed, and thus the regions 313 through 315 may be divided from each other.

As illustrated in FIG. 3B or 3C, gas distribution pipes 317 are in communication with each of the regions 313 through 315 divided by such a dividing structure, and the gases are supplied into the regions 313 through 315 through the gas distribution pipes 317. That is, the gas distribution pipes 317, which are respectively in communication with the regions 313 through 315 [i.e., the same number of the gas distribution pipes 317 as the regions 313 through 315], are installed in the gas supply plate 310. Also, the gas distribution pipes 317 may be disposed to be embedded in the processing space top plate portion 311 as illustrated in FIG. 3B or 3C, but the present invention is not limited thereto, and may be disposed to be exposed above the processing space top plate portion 311.

Also, as illustrated in FIG. 3D, gas exhaust pipes 318, which are respectively in communication with the plurality of exhaust regions 316, are installed in the gas supply plate 310, and the gas in each of the exhaust regions 316 is exhausted through the gas exhaust pipes 318. The gas exhaust pipes 318 are respectively installed to be located at inner peripheral sides of the exhaust regions 316. The gas exhaust pipes 318 are aggregated into one pipe in the vicinity of the circumferential center of the gas supply plate 310, and the aggregated pipe is formed to extend upward.

Also, the exhaust may be performed through additional exhaust pipes, which are installed to exhaust the entire inside of the reaction container, as well as through only the gas exhaust pipes 318.

### (Plasma Generating Unit)

Also, a plasma generating unit which plasmatizes the supplied processing gas is installed in the reaction gas supply region 314, to which a reaction gas is supplied, among the regions 313 through 315 divided by the dividing structure. The processing of the wafer 200 may be performed in the reaction gas supply region 314 with a low temperature by plasmatizing the processing gas. Also, the plasma generating unit will be described in detail below.

### (Gas Inlet Shaft)

A gas inlet shaft 320 is used to introduce various gases into the processing space formed on the susceptor 217. Therefore, as illustrated in FIG. 2, the gas inlet shaft 320 is formed in a cylindrical shaft shape having the same axis as the gas supply plate 310. The gas supply plate 310 is mounted under the shaft of the gas inlet shaft 320.

As illustrated in FIG. 4, a plurality of gas supply pipes 323a-323c are installed in the shaft of the gas inlet shaft 320, and a gas exhaust pipe 324 is installed at the center of the shaft thereof. The number of the plurality of gas supply pipes 323a-323c corresponds to the number of gases supplied onto the wafer 200 placed on the susceptor 217 by the gas supply plate 310. For example, when three types of gases such as a source gas, a reaction gas and a purge gas are supplied onto the wafer 200, the plurality of gas supply pipes 323a-323c are respectively installed corresponding to the three types of gases.

The gas supply pipes 323a-323c are intended to flow different types of gases (e.g., any one of a source gas, a reaction gas and a purge gas) and respectively introduce the gases into the gas supply regions 313 through 315. To this end, the gas supply pipes 323a-323c are in communication with the gas distribution pipes 317 of the gas supply plate 310 when the gas supply plate 310 is mounted on the gas inlet shaft 320. Specifically, the gas supply pipe 323a in which a source gas flows is in communication with the gas distribution pipes 317 leading to the source gas supply region 313. Also, the gas supply pipe 323b in which a reaction gas flows is in communication with the gas distribution pipes 317 leading to the reaction gas supply region 314. Also, the gas supply pipe 323c in which a purge gas flows is in communication with the gas distribution pipes 317 leading to the inert gas supply region 315.

The gas exhaust pipe 324 is configured to be in communication with an aggregate portion of the gas exhaust pipe 318 of the gas supply plate 310 when the gas supply plate 310 is mounted on the gas inlet shaft 320. When the gas exhaust pipe 324 is installed at the center of the shaft of the gas inlet shaft 320, since a diameter of the gas exhaust pipe 324 may be easily increased, the exhaust conductance of the gas exhaust pipe 324 can be maximized as a result of the increased diameter.

Also, according to the relative position movement of the susceptor 217 and the cartridge head 300, when the cartridge head 300 is configured to be rotatable, a magnetic fluid seal 331 is disposed between a reaction container ceiling portion 33 through which the gas inlet shaft 320 passes and a flange unit 325 installed on a cylindrical outer peripheral surface of the gas inlet shaft 320.

### (Gas Supply and Exhaust System)

A gas supply and exhaust system to be described below is connected to the gas inlet shaft 320 in order to perform the supply and exhaust of various gases onto and from the wafer 200 placed on the susceptor 217.

### (Source Gas Supply Unit)

A source gas supply pipe 411 is connected to the gas supply pipe 323a of the gas inlet shaft 320. In the source gas supply pipe 411, a source gas supply source 412, a mass flow controller (MFC) 413 serving as a flow rate controller (a flow rate control unit) and a valve 414 serving as an opening and closing valve are sequentially installed from an upstream end. According to such a configuration, a source gas is supplied into the gas supply pipe 323a.

The source gas is one of the processing gases supplied onto the wafer 200, and for example, is a source gas obtained by evaporating titanium tetrachloride (TiCl4) which is a metal liquid source containing a titanium (Ti) element (that is, TiCl4 gas). The source gas may be in any one of a solid state, a liquid state or a gaseous state under room temperature and normal pressure. When the source gas is in a liquid state under room temperature and normal pressure, a vaporizer (not illustrated) may be installed between the source gas supply source 412 and the MFC 413. Also, a heater is installed in the entirety of components from the source gas supply source 412 to the gas inlet shaft 320, and may be configured to heat the components to maintain the vaporization state of the gas. Here, the case in which the source gas is in a gaseous state will be described.

Also, a gas supply system (not illustrated) for supplying an inert gas which serves as a carrier gas of the source gas may be connected to the source gas supply pipe 411. Specifically, for example, nitrogen (N2) gas may be used as the inert gas which serves as a carrier gas. Also, as the inert gas, in addition to the N2 gas, rare gases such as helium (He) gas, neon (Ne) gas, argon (Ar) gas and the like may be used.

A source gas supply unit mainly includes the source gas supply pipe 411, the MFC 413 and the valve 414. Also, the source gas supply source 412 may be included in the source gas supply unit.

### (Reaction Gas Supply Unit)

A reaction gas supply pipe 421 is connected to the gas supply pipe 323b of the gas inlet shaft 320. In the reaction gas supply pipe 421, a reaction gas supply source 422, an MFC 423 serving as a flow rate controller (a flow rate control unit) and a valve 424 serving as an opening and closing valve are sequentially installed from an upstream end. According to such a configuration, a reaction gas is supplied into the gas supply pipe 323b.

The reaction gas is one of the processing gases supplied onto the wafer 200, and for example, ammonia (NH₃) gas is used as the reaction gas.

Also, a gas supply system (not illustrated) for supplying an inert gas which serves as a carrier gas or dilution gas of the reaction gas may be connected to the reaction gas supply pipe 421. Specifically, for example, N₂ gas may be used as the inert gas which serves as a carrier gas or dilution gas. In addition to the N₂ gas, rare gases such as helium (He) gas, neon (Ne) gas, argon (Ar) gas and the like may be used as the inert gas.

A reaction gas supply unit mainly includes the reaction gas supply pipe 421, the MFC 423 and the valve 424. Also, the reaction gas supply source 422 may be included in the reaction gas supply unit.

### (Inert Gas Supply Unit)

An inert gas supply pipe 431 is connected to the gas supply pipe 323c of the gas inlet shaft 320. In the inert gas supply pipe 431, an inert gas supply source 432, an MFC 433 serving as a flow rate controller (a flow rate control unit) and a valve 434 serving as an opening and closing valve are sequentially installed from an upstream end. According to such a configuration, an inert gas is supplied into the gas supply pipe 323c.

The inert gas serves as a purge gas such that the source gas and the reaction gas are not mixed on a surface of the wafer 200. Specifically, for example, N₂ gas may be used as the inert gas. Also, in addition to the N₂ gas, rare gases such as helium (He) gas, neon (Ne) gas, argon (Ar) gas and the like may be used as the inert gas.

An inert gas supply unit mainly includes the inert gas supply pipe 431, the inert gas supply source 432, the MFC 433 and the valve 434.

### (Gas Exhaust Unit)

A gas exhaust pipe 441 is connected to the gas exhaust pipe 324 installed at the center of the shaft of the gas inlet shaft 320 at a position of the vicinity of the upper end thereof. A valve 442 is installed in the gas exhaust pipe 441. Also, a pressure controller 443 which controls the inside of the processing space with a predetermined pressure based on a result detected by a pressure sensor (not illustrated) is installed in a downstream side of the valve 442 of the gas exhaust pipe 441. Also, a vacuum pump 444 is installed in a downstream side of the pressure controller 443 of the gas exhaust pipe 441. According to such a configuration, the gas exhaust is performed from the inside of the gas exhaust pipe 324 to the outside of the gas inlet shaft 320. Also, an exhaust pipe for exhausting the entire inside of the substrate processing apparatus may be merged with the valve 442, or an additionally installed valve may be merged with the vacuum pump 444.

A gas exhaust unit mainly includes the gas exhaust pipe 441, the valve 442, the pressure controller 443 and the vacuum pump 444.

### (Controller)

Also, as illustrated in FIG. 1, the substrate processing apparatus according to the first embodiment includes the controller 221 which controls the operations of the respective units of the substrate processing apparatus.

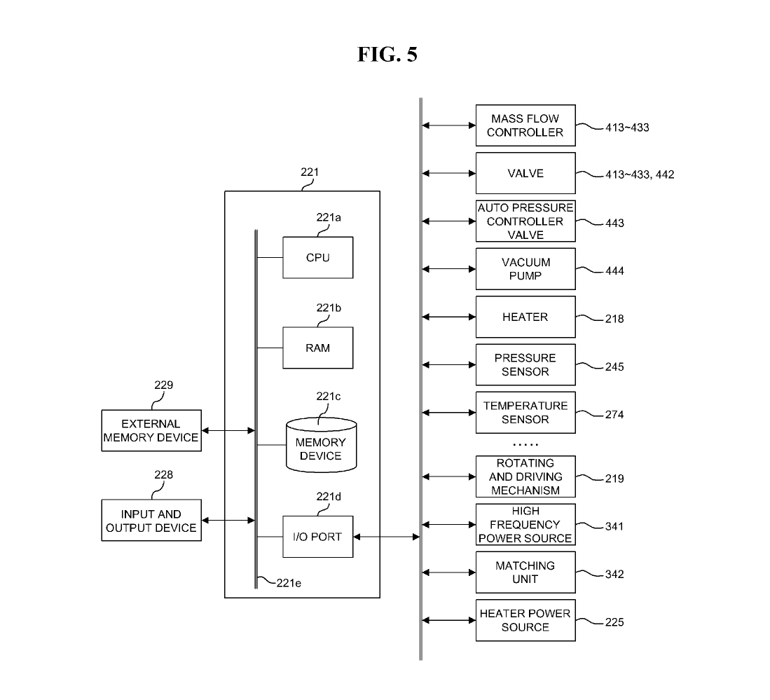

FIG. 5 is a block diagram schematically illustrating an example of a configuration of the controller included in the substrate processing apparatus according to the first embodiment. As illustrated in FIG. 5, the controller 221 serving as a control unit (a control device) is configured as a computer that includes a central processing unit (CPU) 221a, a random access memory (RAM) 221b, a memory device 221c and an input-and-output (I/O) port 221d. The RAM 221b, the memory device 221c and the I/O port 221d are configured to exchange data with the CPU 221a through an internal bus 221e. An I/O device 228 configured as, for example, a touch panel or the like is connected to the controller 221.

The memory device 221c is configured as, for example, a flash memory, a hard disk drive (HDD) and the like. A control program for controlling operations of the substrate processing apparatus 100, a process recipe describing sequences or conditions of substrate processing to be described below or the like are readably stored in the memory device 221c. Also, the process recipe, which is a combination of sequences, causes the controller 221 to execute each sequence in a substrate processing process to be described below in order to obtain a predetermined result, and functions as a program. Hereinafter, such a program recipe, a control program and the like are collectively and simply called a “program.” Also, when the term “program” is used in this specification, it may refer to one or both of the program recipe and the control program. Also, the RAM 221b is configured as a memory area (a work area) in which program, calculating data, process data and the like read by the CPU 221a are temporarily stored.

The I/O port 221d is connected to the above-described MFCs 413-433, the valves 414-434 and 442, a pressure sensor 245, the pressure controller 443 and the vacuum pump 444 of the gas exhaust unit, the heater 218, a temperature sensor 274, the rotating and driving mechanism 219 and a heater power source 225 of the susceptor 217 and a high frequency power source 341 and a matching unit 342 of the plasma generating unit and the like.

The CPU 221a is configured to read and execute the control program from the memory device 221c, and read the process recipe from the memory device 221c according to an input of a manipulating command from the I/O device 228. Also, to comply with the content of the read process recipe, the CPU 221a is configured to control a flow rate adjusting operation of various types of gases by the MFCs 413-433, opening or closing operations of the valves 414-434 and 442, a pressure adjusting operation based on the opening or closing of the pressure controller 443 and the pressure sensor 245, a temperature regulating operation by the heater 218 based on the temperature sensor 274, starting or stopping the vacuum pump 444, a rotational velocity regulating operation of the rotating and driving mechanism 219, power supplying by the high frequency power source 341 or power supplying by the heater power source 225, or is configured to perform the impedance control by the matching unit 342.

Also, the controller 221 is not limited to being configured as a dedicated computer but may be configured as a general-purpose computer. For example, the controller 221 according to the present embodiment may be configured by preparing an external memory device 229 (for example, a magnetic tape, a magnetic disk such as a flexible disk and a hard disk, an optical disc such as a compact disc (CD) and a digital video disc (DVD), a magneto-optical disc such as an MO, and a semiconductor memory such as a Universal Serial Bus (USB) memory and a memory card) recording the above program, and then installing the program in the general-purpose computer using the external memory device 229. Also, the method of supplying the program to the computer is not limited to supply through the external memory device 229. For example, a communication line such as the Internet or a dedicated line may be used to supply the program regardless the external memory device 229. Also, the memory device 221c or the external memory device 229 is configured as a non-transitory computer-readable recording medium. Hereinafter, these are also collectively referred to simply as a recording medium. Also, when the term “recording medium” is used in this specification, it refers to one or both of the memory device 221c and the external memory device 229.

### (3) Substrate Processing Process

Next, as a process among manufacturing processes of a semiconductor apparatus (a semiconductor device) according to the first embodiment, the substrate processing process performed using the process chamber 202a including the above-described reaction container will be described. Also, in the following description, operations of respective units constituting the process chamber 202a of the substrate processing apparatus 100 are controlled by the controller 221.

Here, an example in which TiCl₄ gas obtained by evaporating TiCl₄ is used as a source gas (a first process gas), NH₃ gas is used as a reaction gas (a second process gas), and a titanium nitride (TiN) film serving as a metal thin film is formed on the wafer 200 by alternately supplying these gases will be described.

### (Basic Processing Operation in Substrate Processing Process)

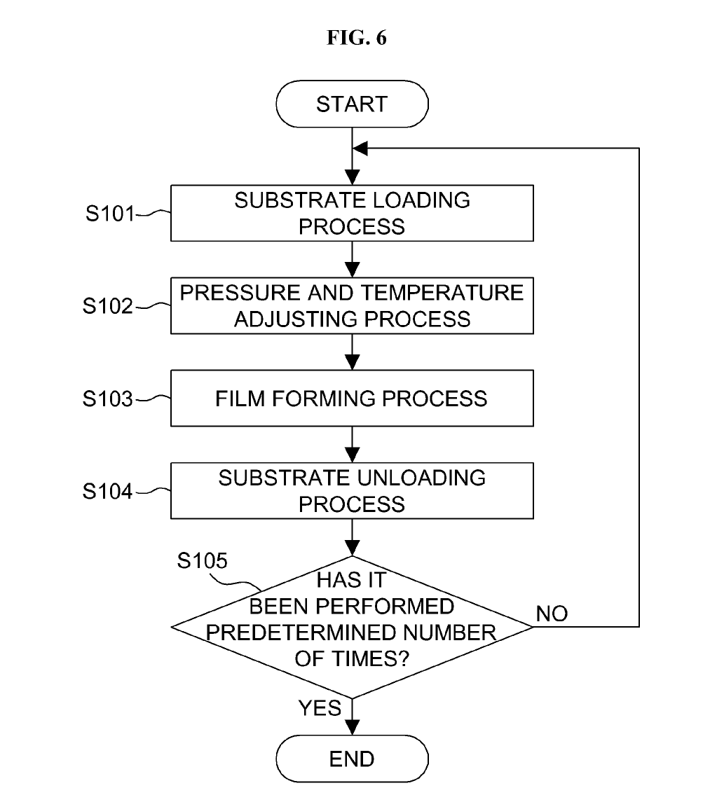

First, a basic processing operation in the substrate processing process in which a thin film is formed on the wafer 200 will be described. FIG. 6 is a flowchart illustrating the substrate processing process according to the first embodiment.

### (Substrate Loading Process: S101)

In the process chamber 202a, first, as a substrate loading process (S101), the gate valve 244a is opened, and a predetermined number (e.g., five) of wafers 200 are loaded into the reaction container using the vacuum transfer robot 112. Each of the wafers 200 is placed onto the same surface of the susceptor 217 based on a rotary shaft of the susceptor 217 so as not to overlap. The vacuum transfer robot 112 is retracted to the outside of the reaction container, the gate valve 244a is closed, and the inside of the reaction container is sealed.

### (Pressure and Temperature Adjusting Process: S102)

After the substrate loading process (S101), a pressure and temperature adjusting process (S102) is performed. In the pressure and temperature adjusting process (S102), after the inside of the reaction container is sealed in the substrate loading process (S101), an operation of the process chamber 202a is controlled such that a pressure in the reaction container is set to a predetermined pressure by operating the gas exhaust system (not illustrated) connected to the reaction container. The predetermined pressure is a processing pressure at which a TiN film can be formed in a film forming process (S103) to be described below, for example, a processing pressure such that a source gas supplied onto the wafer 200 is not self-decomposed. Specifically, the processing pressure may be set to a pressure in a range of 50 Pa to 5,000 Pa. The processing pressure is also maintained in the film forming process (S103) to be described below.

Also, in the pressure and temperature adjusting process (S102), the operation of the process chamber 202a is controlled such that a temperature of the surface of the wafer 200 is set to a predetermined temperature by supplying power to the heater 218 embedded in the susceptor 217. In this case, a temperature of the heater 218 is adjusted by controlling power supplied to the heater 218 based on information on the temperature detected by the temperature sensor 274. The predetermined temperature is a processing temperature at which a TiN film can be formed in the film forming process (S103) to be described below, for example, a processing temperature such that the source gas supplied onto the wafer 200 is not self-decomposed. Specifically, the processing temperature may be set to room temperature or more and 500° C. or less, and preferably, room temperature or more and 400° C. or less. The processing temperature is also maintained in the film forming process (S103) to be described below.

### (Film Forming Process: S103)

After the pressure and temperature adjusting process (S102), the film forming process (S103) is performed. Processing operations performed in the film forming process (S103) are mainly divided into a relative position movement processing operation and a gas supply and exhaust processing operation. Also, the relative position movement processing operation and the gas supply and exhaust processing operation will be described in detail below.

### (Substrate Unloading Process: S104)

Next, after the film forming process (S103) as described above, a substrate unloading process (S104) is performed. In the substrate unloading process (S104), in reverse order to the case of the already described substrate loading process (S101), the processed wafer 200 is unloaded to the outside of the reaction container using the vacuum transfer robot 112.

(Process of Determining Number of Times Processing has been Performed: S105)

After the wafer 200 is unloaded, the controller 221 determines whether or not the substrate loading process (S101), the pressure and temperature adjusting process (S102), the film forming process (S103) and the substrate unloading process (S104) have been performed in series a predetermined number of times (S105). When it is not determined that these processes have been performed the predetermined number of times, the process advances to the substrate loading process (S101) in order to start the processing of a next standby wafer 200. Also, when it is determined that these processes have been performed the predetermined number of times, a cleaning process is performed on the inside of the reaction container and the like, as required, and then the respective series of processes are completed. Also, since the cleaning process may be performed using a known technique, description thereof is omitted herein.

### (Relative Position Movement Processing Operation)

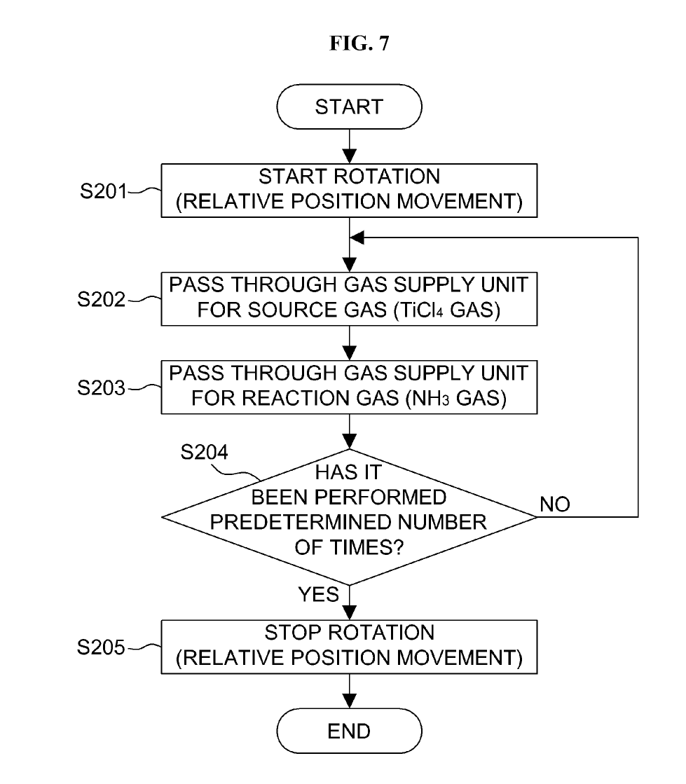

Next, the relative position movement processing operation performed in the film forming process (S103) will be described. For example, the relative position movement processing operation is a processing operation in which the susceptor 217 is rotated and a relative position of each of the wafers 200 placed on the susceptor 217 and the cartridge head 300 is moved. FIG. 7 is a flowchart illustrating the relative position movement processing operation performed in the film forming process of FIG. 6 in detail.

In the relative position movement processing operation performed in the film forming process (S103), first, relative position movement between the susceptor 217 and the cartridge head 300 starts by driving the rotation of the susceptor 217 by the rotating and driving mechanism 219 (S201). Accordingly, the wafers 200 placed on the susceptor 217 sequentially passes below the gas supply regions 313 through 315 on the gas supply plate 310 of the cartridge head 300.

In this case, the gas supply and exhaust processing operation to be described in detail below starts in the cartridge head 300. Accordingly, the source gas (TiCl₄ gas) is supplied into each of the source gas supply regions 313 of the gas supply plate 310, and the reaction gas (NH₃ gas) is supplied into each of the reaction gas supply regions 314.

Here, when considering any of the wafers 200, the wafer 200 passes through the source gas supply region 313 by the rotation of the susceptor 217 starting (S202). In this case, the source gas supply region 313 is adjusted to a processing pressure and a processing temperature at which the source gas is not self-decomposed. Accordingly, when the wafer 200 passes through the source gas supply region 313, gas molecules of the source gas (TiCl₄ gas) are adsorbed onto the surface of the wafer 200. Also, passing time when the wafer 200 passes through the source gas supply region 313, that is, supply time of the source gas, is adjusted to, for example, 0.1 second to 20 seconds.

When the wafer 200 passes through the source gas supply region 313, the wafer 200 passes through the inert gas supply region 315 into which the inert gas (N₂ gas) is supplied, and then passes through the reaction gas supply region 314 (S203). In this case, the reaction gas (NH₃ gas) is supplied into the reaction gas supply region 314. Accordingly, when the wafer 200 passes through the reaction gas supply region 314, the reaction gas is uniformly supplied onto the surface of the wafer 200, and a TiN film having a thickness of less than one atomic layer (less than 1 Å) is generated on the wafer 200 by the reaction with the gas molecules of the source gas adsorbed onto the wafer 200. Passing time when the wafer 200 passes through the reaction gas supply region 314, that is, supply time of the reaction gas, is adjusted to, for example, 0.1 second to 20 seconds.

Also, in order to uniformly perform an initial TiCl4-NH3 cycle on all the wafers 200, it may be configured such that the supply of NH₃ gas into the reaction gas supply region 314 is stopped, TiCl₄ is adsorbed onto all the wafers 200, and then NH₃ is supplied until all the wafers 200 pass through the source gas supply region 313.

Also, in this case, in the reaction gas supply region 314, the reaction gas is supplied onto the wafer 200 by plasmatizing the reaction gas. By plasmatizing the reaction gas, it is possible to process the processing at a low temperature.

As described above, the controller 221 determines whether or not a cycle of the passing operation of the source gas supply region 313 and the passing operation of the reaction gas supply region 314 is performed a predetermined number of times (n cycles) (S204). When it is determined that the cycle is performed the predetermined number of times, the TiN film having a desired film thickness is formed on the wafer 200. That is, in the film forming process (S103), by performing the relative position movement processing operation, a cyclic processing operation, which is a process in which other processing gases are alternately supplied onto the wafer 200 is repeated, is performed. Also, in the film forming process (S103), by performing the cyclic processing operation on each of the wafers 200 placed on the susceptor 217, TiN films are simultaneously formed on the wafers 200 in parallel.

Then, when the cyclic processing operation of the predetermined number of times is completed, the controller 221 completes the driving of the rotation of the susceptor 217 by the rotating and driving mechanism 219, and stops the relative position movement of the susceptor 217 and the cartridge head 300 (S205). Accordingly, the relative position movement processing operation is completed. Also, when the cyclic processing operation of the predetermined number of times is completed, the gas supply and exhaust processing operation is also completed.

### (Gas Supply and Exhaust Processing Operation)

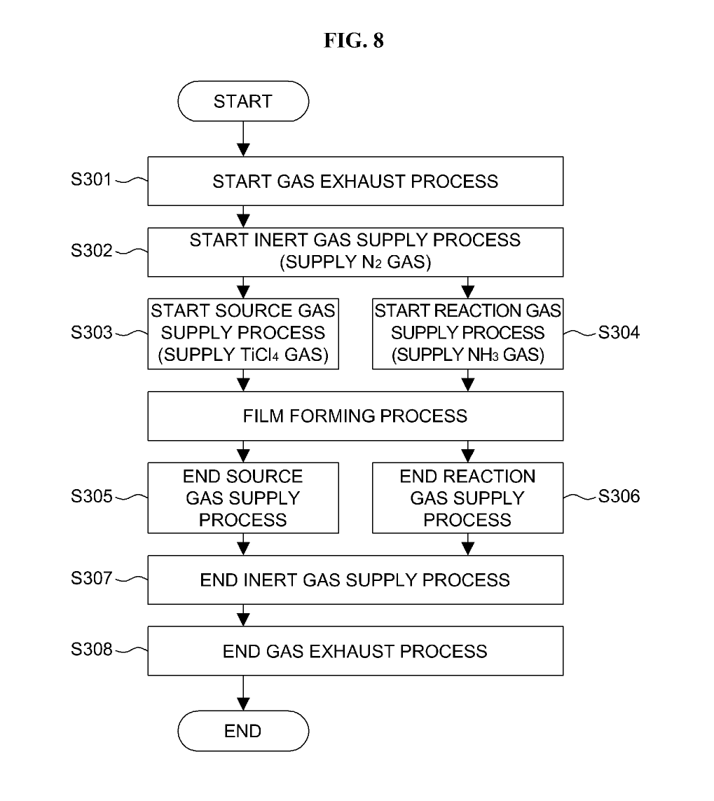

Next, the gas supply and exhaust processing operation performed in the film forming process (S103) will be described. The gas supply and exhaust processing operation is a processing operation in which the supply and exhaust of various gases onto and from the wafers 200 placed on the susceptor 217 are performed. FIG. 8 is a flowchart illustrating the gas supply exhaust processing operation performed in the film forming process of FIG. 6 in detail.

In the gas supply and exhaust processing operation performed in the film forming process (S103), first, a gas exhaust process (S301) starts. In the gas exhaust process (S301), the valve 442 is opened while operating the vacuum pump 444. Accordingly, in the gas exhaust process (S301), the gas in each of the gas supply regions 313 through 315 is exhausted through each of the exhaust regions 316 of the gas supply plate 310 to the outside of the reaction container through the gas exhaust pipes 318 respectively in communication with the exhaust regions 316, the gas exhaust pipe 324 of the gas inlet shaft 320 in communication with an aggregate portion of the gas exhaust pipes 318 and the gas exhaust pipe 441 connected to a position of the vicinity of the upper end of the gas exhaust pipe 324. In this case, a pressure in the gas supply regions 313 through 315 and the exhaust region 316 are controlled to a predetermined pressure by the pressure controller 443. Also, the gas diffused to the outside of the gas supply plate 310 is rapidly exhausted by an exhaust port which exhausts the entire inside of the substrate processing apparatus.

The gas exhaust process (S301) starts, and then an inert gas supply process (S302) starts. In the inert gas supply process (S302), the valve 434 of the inert gas supply pipe 431 is opened, and the MFC 433 adjusts a flow rate of an inert gas to a predetermined flow rate. Accordingly, in the inert gas supply process (S302), the inert gas (N2 gas) is introduced into the gas supply pipe 323c of the gas inlet shaft 320 to which the inert gas supply pipe 431 is connected, and the inert gas is supplied into the inert gas supply region 315 through the gas distribution pipe 317 in communication with the gas supply pipe 323c. A supply flow rate of the inert gas is set to, for example, a flow rate in a range of 100 sccm to 10,000 sccm. When the inert gas supply process (S302) is performed, an air curtain of the inert gas is formed in the inert gas supply region 315 interposed between the source gas supply region 313 and the reaction gas supply region 314.

The inert gas supply process (S302) starts, and then a source gas supply process (S303) and a reaction gas supply process (S304) start.

In the source gas supply process (S303), the source gas (i.e., TiCl₄ gas) is generated in advance (preliminarily vaporized) by vaporizing a source (TiCl₄). The preliminary vaporization of the source gas may be performed in parallel with the above-described substrate loading process (S101), pressure and temperature adjusting process (S102) or the like. This is because a predetermined time is required in order to reliably generate the source gas.

When the source gas is generated, in the source gas supply process (S303), the valve 414 of the source gas supply pipe 411 is opened, and the MFC 413 adjusts a flow rate of a source gas to a predetermined flow rate. Accordingly, in the source gas supply process (S303), the source gas (TiCl₄ gas) is introduced into the gas supply pipe 323a of the gas inlet shaft 320 to which the source gas supply pipe 411 is connected, and is supplied into the source gas supply region 313 through the gas distribution pipe 317 in communication with the gas supply pipe 323a. A supply flow rate of the source gas is set to, for example, a flow rate in a range of 10 sccm to 3,000 sccm.

In this case, the inert gas (N₂ gas) may be supplied as a carrier gas of the source gas. A supply flow rate of the inert gas in this case is set to, for example, a flow rate in a range of 10 sccm to 5,000 sccm.

When the source gas supply process (S303) is performed, the source gas (TiCl₄ gas) is uniformly diffused into all regions in the source gas supply region 313. Since the gas exhaust process (S301) has already started, the source gas diffused into the source gas supply region 313 is exhausted from the inside of the source gas supply region 313 through the exhaust region 316 by the gas exhaust pipe 318 in communication with the exhaust region 316. Also, in this case, an air curtain of the inert gas is formed in the adjacent inert gas supply region 315 by starting the inert gas supply process (S302). Therefore, the source gas supplied into the source gas supply region 313 is not discharged into the adjacent inert gas supply region 315 through the exhaust region 316.

Also, in the reaction gas supply process (S304), the valve 424 of the reaction gas supply pipe 421 is opened, and the WC 423 adjusts a flow rate of a reaction gas to a predetermined flow rate. Accordingly, in the reaction gas supply process (S304), the reaction gas is introduced into the gas supply pipe 323b of the gas inlet shaft 320 to which the reaction gas supply pipe 421 is connected, and the reaction gas is supplied into the reaction gas supply region 314 through the gas distribution pipe 317 in communication with the gas supply pipe 323b. A supply flow rate of the reaction gas is set to, for example, a flow rate in a range of 10 sccm to 10,000 sccm.

Also, in order to uniformly perform the initial TiCl₄—NH₃ cycle on all the wafers 200, until all the wafers 200 pass through the source gas supply region 313, it may be configured such that the supply of NH₃ gas into the reaction gas supply region 314 is stopped, TiCl₄ is adsorbed onto all the wafers 200, and then NH₃ is supplied.

In this case, the inert gas (N₂ gas) may be supplied as a carrier gas or dilution gas of the reaction gas. A supply flow rate of the inert gas in this case is set to, for example, a flow rate in a range of 10 sccm to 5,000 sccm.

Also, in the reaction gas supply process (S304), plasma is generated by activating the reaction gas (NH₃ gas), and the plasmatized reaction gas is supplied onto the wafer 200.

When the reaction gas supply process (S304) is performed, the reaction gas (NH₃ gas) is uniformly diffused into all regions in the reaction gas supply region 314. Since the gas exhaust process (S301) has already started, the reaction gas diffused into the reaction gas supply region 314 is exhausted from the inside of the reaction gas supply region 314 through the exhaust region 316 by the gas exhaust pipe 318 in communication with the exhaust region 316. Also, in this case, an air curtain of the inert gas is formed in the adjacent gas supply region 315 by starting the inert gas supply process (S302). Therefore, the reaction gas supplied into the reaction gas supply region 314 is not discharged into the adjacent inert gas supply region 315 through the exhaust region 316.

The above-described processes (S301 to S304) are sequentially performed or performed in parallel during the film forming process (S103). However, start timing may be set to perform the above-described sequence in order to improve the sealing characteristics by the inert gas, but the present invention is not limited thereto. When there is no concern that a target predetermined film thickness has an error of less than one atomic layer (1A), the processes (S301 to S304) may be simultaneously performed. However, since a difference in the film thickness or film quality in each the wafer 200 may occur by a gas initially adsorbed according to a film type, the gases initially exposed to the wafers 200 is preferably the same.

By performing the above-described processes (S301 to S304) in parallel, in the film forming process (S103), the wafers 200 placed on the susceptor 217 sequentially pass through a lower portion of the source gas supply region 313 in a source gas atmosphere and a lower portion of the reaction gas supply region 314 in a reaction gas atmosphere. Also, since the inert gas supply region 315 and the exhaust region 316, which are in an inert gas atmosphere, are interposed between the source gas supply region 313 and the reaction gas supply region 314, the source gas and the reaction gas, which are supplied onto the wafers 200, are not mixed.

When the gas supply and exhaust processing operation is completed, first, the source gas supply process is completed (S305), and at the same time the reaction gas supply process is completed (S306). After the inert gas supply process is completed (S307), the gas exhaust process is completed (S308). However, the completion timings of the processes (S305 to S308) are the same as the above-described start timing, and the processes (S305 to S308) may be completed at different timings or at the same timing.

### (4) Plasma Generation

Next, in the above-described substrate processing process, processing in which the reaction gas (NH₃ gas) supplied into the reaction gas supply region 314 is plasmatized and a configuration of the plasma generating unit will be described in detail.

The plasma generating unit generates an active species of the reaction gas by plasmatizing the reaction gas (NH₃ gas) supplied into the reaction gas supply region 314. The active species refers to reaction intermediates having high reactivity which, for example, correspond to the radicals which are highly reactive particles. The reactivity of the plasma is increased by the function of the active species. That is, when the active species of the reaction gas is generated by plasmatizing the reaction gas, the plasma generating unit serves as a plasma generator in the present invention.

### (Configuration of Plasma Generating Unit)

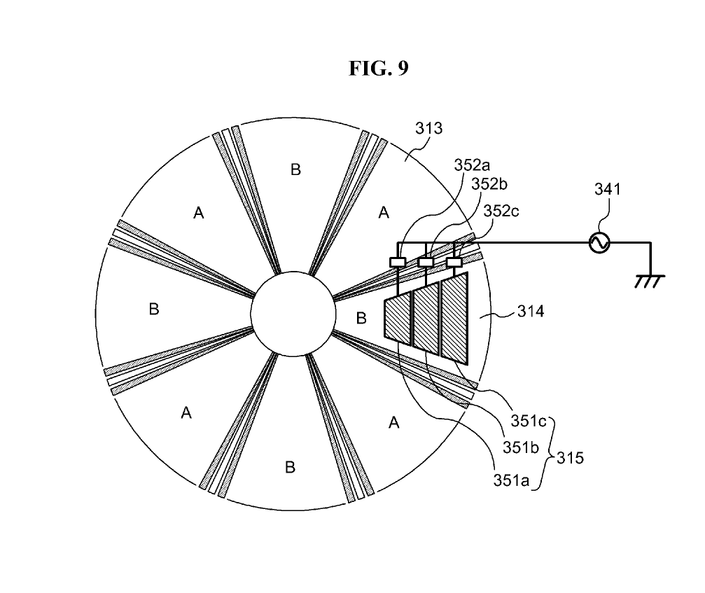

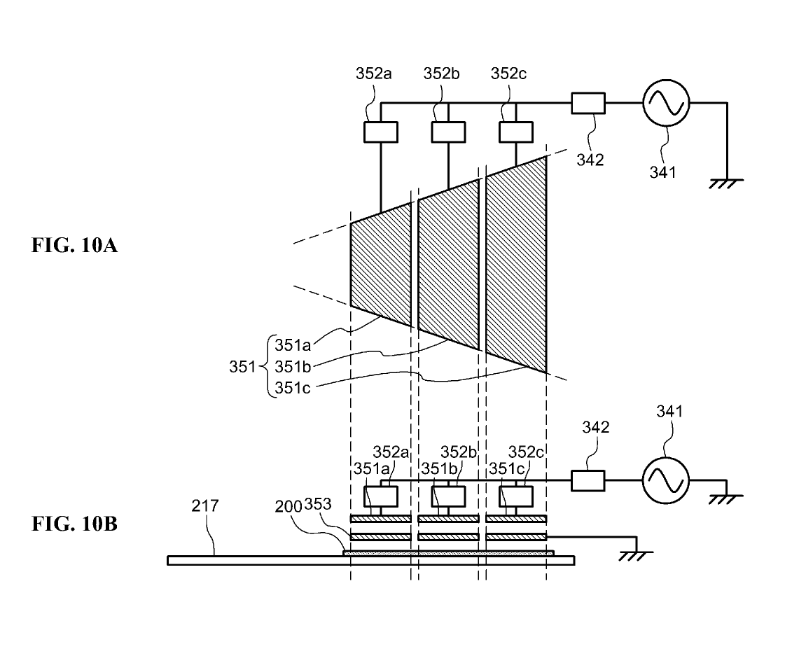

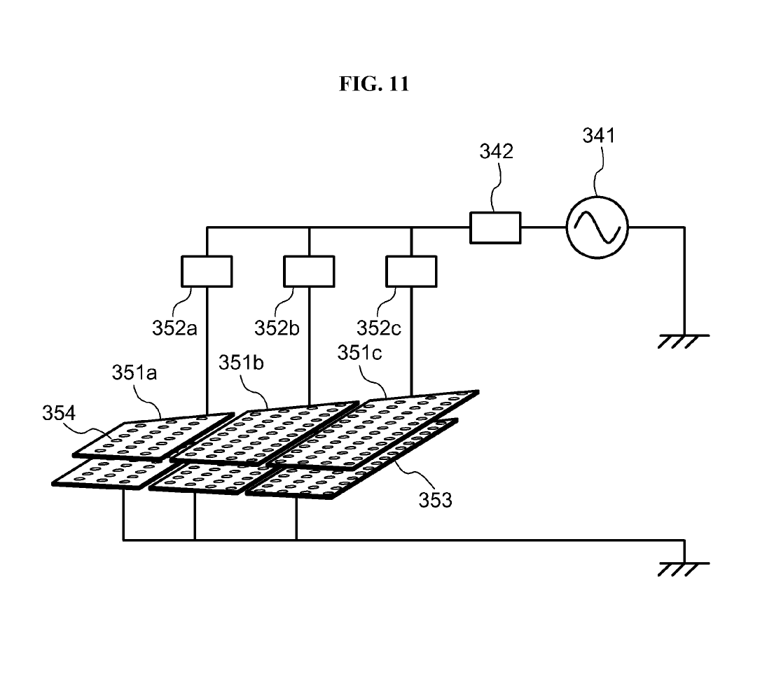

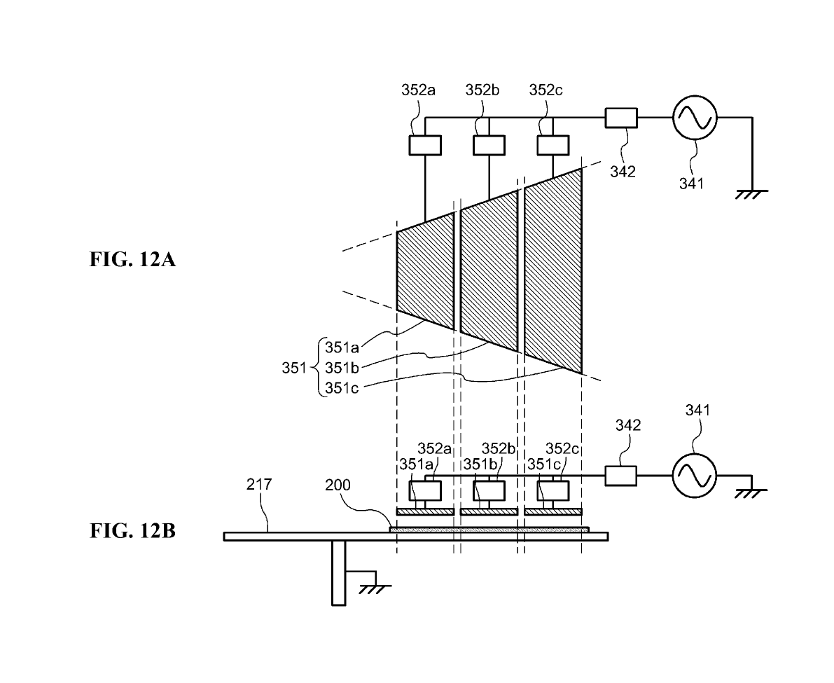

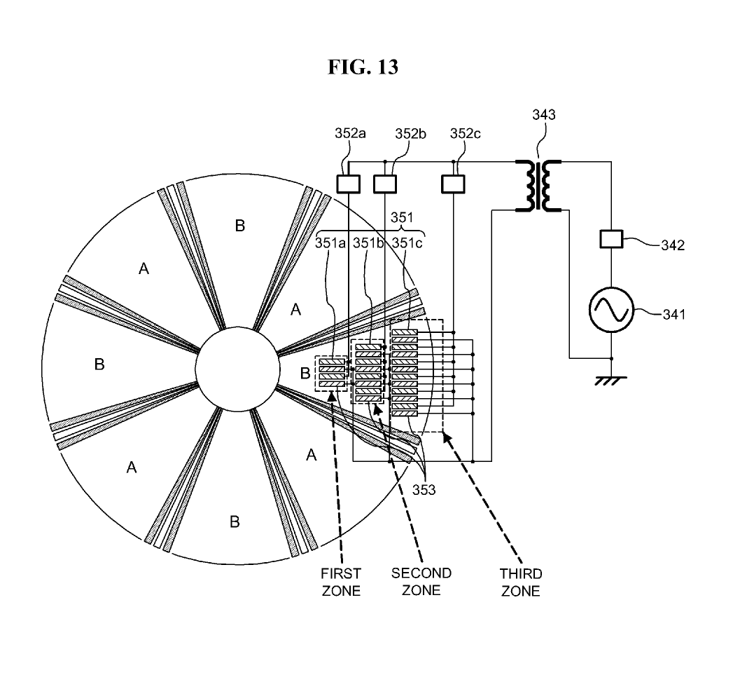

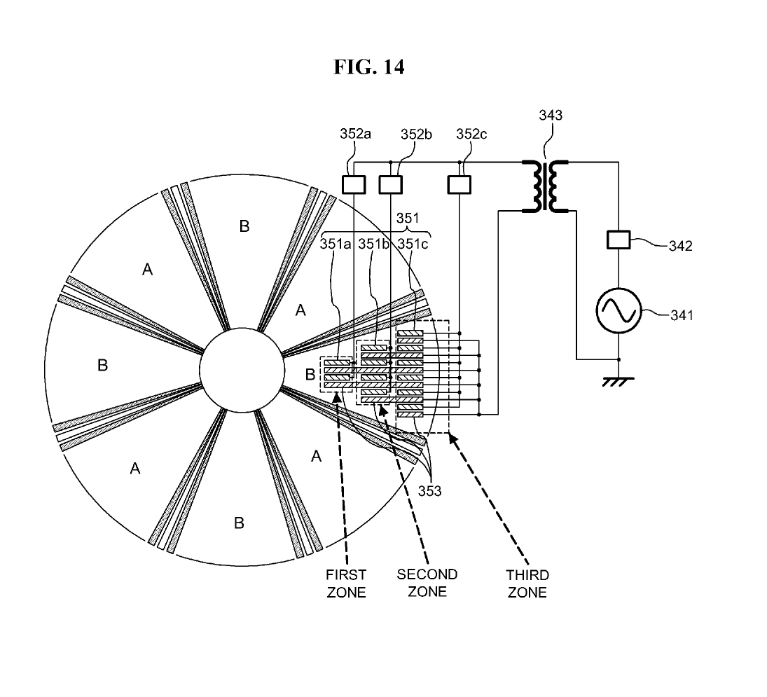

Hereinafter, the configuration of the plasma generating unit serving as a plasma generator will be described with reference to FIGS. 9 through 14. FIG. 9 is an explanatory diagram schematically illustrating an overview of the plasma generating unit included in the substrate processing apparatus according to the first embodiment. FIGS. 10A and 10B are explanatory diagrams illustrating an example of a configuration of the plasma generating unit included in the substrate processing apparatus according to the first embodiment. FIG. 11 is an explanatory diagram illustrating an example of main components of the plasma generating unit included in the substrate processing apparatus according to the first embodiment. FIGS. 12A and 12B are explanatory diagrams illustrating another example of the configuration of the plasma generating unit included in the substrate processing apparatus according to the first embodiment. FIG. 13 is an explanatory diagram illustrating another example of the configuration of the plasma generating unit included in the substrate processing apparatus according to the first embodiment. FIG. 14 is an explanatory diagram illustrating a modification of still another example of the configuration of the plasma generating unit included in the substrate processing apparatus according to the first embodiment.

As illustrated in FIG. 9, the plasma generating unit includes a plate electrode 351 serving as a high frequency power supply unit disposed in the reaction gas supply region 314 for plasmatizing a reaction gas supplied into the reaction gas supply region 314. High frequency power provided from the high frequency power source 341 is supplied to the plate electrode 351. Also, although the case in which the plate electrode 351 is disposed in one reaction gas supply region 314 is illustrated in the drawing in order to simplify the illustration, the plate electrodes 351 are actually installed in all of the reaction gas supply regions 314 divided by the dividing structure.

Meanwhile, the dividing structure of the gas supply plate 310 is disposed to form the regions 313 through 315 in a radial direction from the circumferential center of the susceptor 217. Accordingly, the reaction gas supply region 314 is divided, for example, in a sector shape in a plan view by the dividing structure. Therefore, the plate electrode 351 disposed in the reaction gas supply region 314 is also formed in a shape corresponding to a planar surface of the reaction gas supply region 314 (e.g., a sector shape in a plan view). That is, the planar surface of the plate electrode 351 does not necessarily have a uniform size in all regions of the reaction gas supply region 314, and the variation of the size occurs in each portion of the reaction gas supply region 314.

Thus, when the variation of the size of the planar surface of the plate electrode 351 occurs in each portion of the reaction gas supply region 314 and the reaction gas in the reaction gas supply region 314 is plasmatized using the plate electrode 351, plasma may be biased to a side at which an area of the plate electrode 351 is large. In the case of the illustrated example, the plasma is focused on an outer peripheral side having a large area, and the variation occurs. When the variation of the plasma distribution occurs, it causes a reduction in in-plane uniformity such as a film thickness, a film quality or the like of a film formed on the wafer 200. Also, since the susceptor 217 is rotated and moved in the reaction container such that the wafer 200, which is a processing target, sequentially passes through the regions 313 through 315, a difference between a gas exposure amount to the wafer 200 at an inner peripheral side and the outer peripheral side while rotating the susceptor 217 may occur. Therefore, in the case of the plasmatizing of the reaction gas, when the plasma distribution is not adjusted in consideration of the difference between the gas exposure amount at each portion of the reaction gas supply region 314, it causes the reduction in the in-plane uniformity such as the film thickness, the film quality or the like of the film formed on the wafer 200.

The plasma generating unit described in the first embodiment is configured to partially adjust a plasma distribution in the reaction gas supply region 314 in order to suppress the reduction in the in-plane uniformity of the film formed on the wafer 200.

Specifically, as illustrated in FIGS. 9 and 10A, the plate electrode 351, which is disposed facing the wafer 200 in order to adjust the in-plane uniformity of the reaction gas supply region 314, is multi-divided in a radial direction of the rotation of the susceptor 217. When the number of divisions of the plate electrode 351 is large, the adjustment of the in-plane uniformity is accurately performed. As the number of divisions of the plate electrode 351 is increased, it causes complexity of the configuration. Therefore, the plate electrode 351 divided into at least two divisions, and preferably three divisions are used. That is, the plate electrode 351 in the present embodiment is divided into three divisions, that is, a plate electrode 351a disposed on a portion of the inner peripheral side in the reaction gas supply region 314 (hereinafter, referred to as “a first zone”), a plate electrode 351b which is adjusted to a first zone in the reaction gas supply region 314 and is disposed on a portion of the outer peripheral side thereof (hereinafter, referred to as “a second zone”) and a plate electrode 351c disposed on a portion of the outer peripheral side located further away than a second zone in the reaction gas supply region 314 (hereinafter, referred to as “a third zone”). In this manner, the plasma generating unit in the present embodiment includes a plurality of plate electrodes 351a-351c (the high frequency power supply unit) respectively installed in each portion of the reaction gas supply region 314.

Also, the plasma generating unit includes impedance adjusting units 352a-352c respectively installed corresponding to the plurality of plate electrodes 351a-351c. The impedance adjusting units 352a-352c respectively adjust power supplied to the plate electrodes 351a-351c. Units configured of known electric circuits may be used as the impedance adjusting units 352a-352c. The impedance adjusting units 352a-352c are connected to the high frequency power source 341 and the matching unit 342. By providing the impedance adjusting units 352a-352c, different power may be supplied into the plate electrodes 351a-351c. Also, when it is possible to supply different power to the plate electrodes 351a-351c, individual high frequency power sources may be connected to the plate electrodes 351a-351c without installation of the impedance adjusting units 352a-352c. However, since the power is divided from one high frequency power source 341 and adjusted by the impedance adjusting units 352a-352c disposed in the middle, the complexity of the device configuration or the increase of the device cost is preferably suppressed.

Also, the plasma generating unit includes a ground electrode 353 disposed between each of the plate electrodes 351a-351c and the wafer 200 as illustrated in FIG. 10B. The ground electrode 353 is electrically grounded. By providing the ground electrodes 353, when the high frequency power supplied from the high frequency power source 341 is supplied to each of the plate electrodes 351a-351c, plasma is generated between each of the plate electrodes 351a-351c and the ground electrode 353. Also, the ground electrode 353 may be formed as a single plate and shared between the plate electrodes 351a-351c, or may be multi-divided same as the plate electrode 351 and may respectively face the plate electrodes 351a-351c. Also, when the ground electrode 353 is divided, a bias between each of the plate electrodes 351a-351c and the ground electrode 353 may be respectively adjusted.

Since the plate electrode 351 and the ground electrode 353 are disposed in the reaction gas supply region 314 into which the reaction gas is supplied, gas supply holes 354 through which the reaction gas passes may be installed as illustrated in FIG. 11 in order to suppress the reduction in the movement of the reaction gas in the reaction gas supply region 314. In this case, formation positions of the gas supply holes 354 are not limited to particular positions, and may be formed at random.

Also, when a plasma generating unit does not include the above-described ground electrode 353, the susceptor 217 may be configured to serve as a ground electrode as illustrated in FIGS. 12A and 12B. In this configuration, when the susceptor 217 is electrically grounded and the high frequency power supplied from the high frequency power source 341 is supplied to the plate electrodes 351a-351c, plasma is generated between each of the plate electrodes 351a-351c and the susceptor 217. Therefore, since plasma is directly radiated onto the wafer 200 placed on the susceptor 217, more active reaction gas is supplied.

Also, when the plasma generating unit includes the ground electrode 353 and the ground electrode 353 is not disposed between each of the plate electrodes 351a-351c and the wafer 200, the ground electrode 353 may be disposed at a position that does not overlap the plate electrodes 351a-351c on a same plane as each of the plate electrodes 351a-351c as illustrated in FIG. 13. That is, each of the plate electrodes 351a-351c and the ground electrode 353 are arranged on a same plane in a comb shape. Even in the comb-shaped arrangement, the high frequency power supplied from the high frequency power source 341 passes through a matching box 342 and an insulation transformer 343, then is respectively adjusted by the impedance adjusting units 352a-352c, and is supplied into each of the plate electrodes 351a-351c as different types of power in each of the first zone to the third zone. With the configuration according to the comb-shaped arrangement, since each of the plate electrodes 351a-351c and the ground electrode 353 are disposed on the same plane, it is helpful for saving space in a vertical direction of the reaction gas supply region 314 [the thickness direction of the wafer 200].

Also, when each of the plate electrodes 351a-351c and the ground electrode 353 are disposed in a comb shape, the ground electrode 353 may not be individually configured in each of the first zone to the third zone, but may be configured to be shared and integrated in the first zone to the third zone as illustrated in FIG. 14. Since all the ground electrodes 353 are potentially ground, it is possible to share in the first zone to the third zone, and the simplification and cost reduction of the electrode configuration may be expected by the sharing of the ground electrodes 353.

### (Plasma Treatment)

Next, processing of plasmatizing a reaction gas in the reaction gas supply region 314 using the plasma processing unit having the above-described configuration will be described.

When plasmatizing the reaction gas in the reaction gas supply region 314, high frequency power is supplied from the high frequency power source 341 to the plate electrode 351 in a state in which a reaction gas in the reaction gas supply region 314 is supplied.

In this case, each of the impedance adjusting units 352a-352c adjusts the high frequency power, which is supplied from the high frequency power source 341, to different types power, and supplies each of the different types of adjusted power to each of the plate electrodes 351a-351c. Specifically the impedance adjusting unit 352a supplies, for example, power adjusted to 400 W into the plate electrode 351a. Also, the impedance adjusting unit 352b supplies, for example, power adjusted to 300 W into the plate electrode 351b. Also, the impedance adjusting unit 352c supplies, for example, power adjusted to 200 W into the plate electrode 351c.

When each of the impedance adjusting units 352a-352c performs the power supply into each of the plate electrodes 351a-351c, plasma is generated between each of the plate electrodes 351a-351c and the ground electrode 353 [or the susceptor 217 when the susceptor 217 serves as the ground electrode]. Additionally, an active species of the reaction gas is generated by plasmatizing the reaction gas in the reaction gas supply region 314.

In this case, different types of power are respectively supplied to the plate electrodes 351a-351c. Therefore, the activity of the active species of the reaction gas generated in the reaction gas supply region 314 is changed in each portion in which each of the plate electrodes 351a-351c is disposed. Specifically, the activity of the reaction gas in the reaction gas supply region 314 is, for example, highest in the first zone in which the plate electrode 351a to which power of 400 W is supplied is disposed, is high in the second zone in which the plate electrode 351b to which power of 300 W is supplied is disposed, and is lowest in the third zone in which the plate electrode 351c to which power of 200 W is supplied is disposed.

That is, when plasmatizing the reaction gas in the reaction gas supply region 314, the activity of the active species generated by supplying different types of power into each of the plate electrodes 351a-351c is changed to be different in each portion of the first zone to the third zone.

Thus, when the activity of the active species of the reaction gas generated in the reaction gas supply region 314 is independently controlled in each portion of the first zone to the third zone, it is possible to manage the variation of the plasma distribution in the reaction gas supply region 314. Specifically, when the activity in the first zone is greater than that in the third zone by independently controlling the activity of the active species in a portion of the inner peripheral side of the reaction gas supply region 314 and a portion of the outer peripheral side thereof, it is possible to correct the variation of the plasma distribution even when the plasma is focused on the outer peripheral side of the plate electrode 351 having a large area and may cause the variation. Also, even when a difference between the gas exposure amount of the inner peripheral side and that of the outer peripheral side may occur, since the plasma distribution may be adjusted in consideration of the difference of the gas exposure amount, the adverse effects caused by the difference of the gas exposure amount may be excluded.

Therefore, when using the reaction gas plasmatized through the plasma treatment, it is possible to suppress the reduction in the in-plane uniformity such as the film thickness, the film quality or the like of the film formed on the wafer 200.

Also, here, in order to suppress the reduction in the in-plane uniformity of the film formed on the wafer 200, the case in which the impedance adjusting units 352a-352c respectively supply power of 400 W to the inner peripheral side, power of 300 W to the intermediate side, and power of 200 W to the outer peripheral side of the plate electrodes 351a-351c is described as an example, but it is just a simple example and is not limited thereto. For example, the impedance adjusting units 352a-352c may adjust to supply the power of 200 W to the inner peripheral side, the power of 300 W to the intermediate side, the power of 400 W to the outer peripheral side in order to provide a desired film thickness gradient to the film formed on the wafer 200.

Also, according to power supplied to each of the plate electrodes 351a-351c, although the size of the supplied power is adjusted in the same manner as described above, it is considered that the frequency or phase of the supplied power is uniform in each portion of the first to third zones and the apply timing to the portion is simultaneous. However, the present invention is not limited thereto, but the frequency, phase and apply timing of the supplied power may be appropriately adjusted in each portion of the first to third zones to be different from each other.

### (5) Effects According to the First Embodiment

According to the first embodiment, one or a plurality of effects to be described below will be obtained.

(a) According to the first embodiment, the active species of the reaction gas is generated by plasmatizing the reaction gas supplied into the reaction gas supply region 314, and the activity of the active species of the reaction gas is independently controlled in each portion of the reaction gas supply region 314 when plasmatizing the reaction gas. Accordingly, the plasma distribution in the reaction gas supply region 314 may be partially adjusted, and thus it is possible to suppress the reduction in the in-plane uniformity such as the film thickness, the film quality or the like of the film formed on the wafer 200.

(b) According to the first embodiment, the activity of the active species of the reaction gas in the portion of the inner peripheral side of the reaction gas supply region 314 and the activity of the portion of the outer peripheral side thereof are independently controlled. Therefore, even when the plurality of wafers 200 are placed on the susceptor 217 and the space on the susceptor 217 is divided by the dividing structure in a radial direction, the reaction gas supply region 314, for example, having a sector shape in a plan view is formed, and accordingly when plasma is focused on the outer peripheral side of the reaction gas supply region 314 and the variation occurs, or even when the difference between the gas exposure amount of the inner peripheral side and the outer peripheral side with respect to the wafer 200 occurs, the plasma distributions at the inner peripheral side and the outer peripheral side may be partially adjusted, and thus it is possible to suppress the reduction in the in-plane uniformity of the wafer 200 in a radial direction of the rotation of the susceptor 217.

(c) Also, according to the first embodiment, the plate electrode 351 to which the power is supplied in the plasma treatment is multi-divided in the radial direction of the rotation of the susceptor 217, and different types of power are supplied to each of the divided plate electrodes 351a-351c (the high frequency power supply unit). Therefore, even after the device is completed [after the plate electrode 351 is assembled], it is possible to partially adjust the plasma distribution in the reaction gas supply region 314 by appropriately setting the supply power to each of the plate electrodes 351a-351c.

(d) Also, according to the first embodiment, the impedance adjusting units 352a-352c respectively installed corresponding to the plate electrodes 351a-351c are provided, and different types of power are supplied to the plate electrodes 351a-351c through the impedance adjusting units 352a-352c thereof. Therefore, for example, in comparison to the case in which high frequency power is respectively connected to each of the plate electrodes 351a-351c, it is possible to respectively supply the desired power to each of the plate electrodes 351a-351c while suppressing the complexity of the device configuration or the increase of the device cost.

### Second Embodiment of the Present Invention

Next, a second embodiment of the present invention will be described with reference to the drawing. However, here, the difference from the above-described first embodiment is mainly described, and description of other points will be omitted.

In the second embodiment, a plasma generating unit is configured differently from that of the first embodiment. The term “plasma generating unit” used herein corresponds to a surface wave plasma (hereinafter, referred to as “SWP”) which is a microwave excited high-density plasma. When using the SWP, plasma having high electron density at a low temperature, which could not be achieved in the case in which the plate electrode 351 is used as in the first embodiment, is generated, and thus it is possible to perform process processing without damage at a low temperature. Also, since the SWP is well known, detailed description thereof is omitted herein.

### (Configuration of the Plasma Generating Unit)

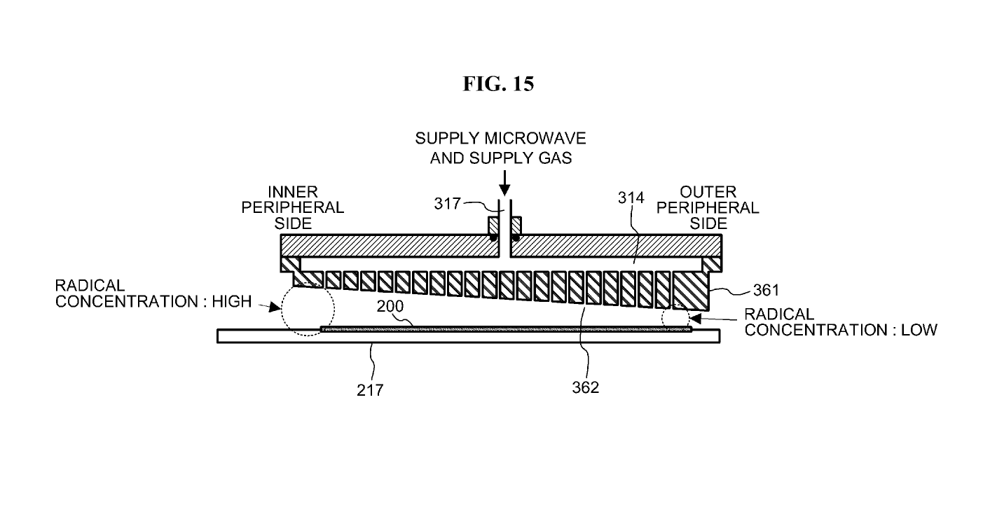

FIG. 15 is an explanatory diagram illustrating an example of a configuration of the plasma generating unit included in the substrate processing apparatus according to the second embodiment. In the second embodiment, a dielectric plate 361 is disposed in the reaction gas supply region 314 as the plasma generating unit corresponding to the SWP. A microwave is supplied to the reaction gas supply region 314 through the gas distribution pipe 317 with the reaction gas, the microwave is introduced into the reaction gas supply region 314 through the dielectric plate 361 to form a surface wave, plasma is excited by the surface wave, and thus an active species of a reaction gas is generated by plasmatizing the reaction gas. Therefore, through holes 362 for introducing the microwave onto the wafer 200 placed on the susceptor 217 are installed in the dielectric plate 361.

However, the dielectric plate 361 is formed such that a distance from the wafer 200 placed on the susceptor 217 is changed in each portion of the reaction gas supply region 314. Specifically, the dielectric plate 361 is formed, for example, such that the distance from the wafer 200 placed on the susceptor 217 is large at the inner peripheral side of the reaction gas supply region 314 and is gradually closer toward the outer peripheral side thereof.

According to the dielectric plate 361 formed in this manner, the activity of the active species of the reaction gas at the inner peripheral side in the reaction gas supply region 314 is different from the activity of the active species of the reaction gas at the outer peripheral side thereof. That is because the distance through which the microwave passes through the dielectric plate 361 is different at the inner peripheral side in the reaction gas supply region 314 from at the outer peripheral side thereof in the same manner as a distance through which the microwave passes through the dielectric plate 361 is small at the inner peripheral side in the reaction gas supply region 314, and the distance through which the microwave passes through the dielectric plate 361 is large at the outer peripheral side in the reaction gas supply region 314. More specifically, that is because a deactivated amount of the microwave is increased as the distance through which the microwave passes through the dielectric plate 361 is increased, and thus a radical concentration (i.e., the activity of the active species of the reaction gas) is decreased.

That is, the dielectric plate 361 in the second embodiment is formed such that the distance from the wafer 200 placed on the susceptor 217 at the inner peripheral side in the reaction gas supply region 314 is different from at the outer peripheral side thereof, and thus is formed such that the plasma distributions at the inner peripheral side and the outer peripheral side in the reaction gas supply region 314 may be adjusted.

### (Effects According to the Second Embodiment)

According to the second embodiment, one or a plurality of effects to be described below will be obtained.

(a) According to the second embodiment, when a thickness of the dielectric plate 361 is changed in a radial direction of the rotation of the susceptor 217, the activity (the radical concentration) of the active species of the reaction gas in the reaction gas supply region 314 may be partially adjusted to be different at the inner peripheral side from the outer peripheral side. That is, the activity of the active species of the reaction gas supplied onto the wafer 200 may be adjusted according to the distance of the through holes 362 in the dielectric plate 361. Therefore, it is possible to suppress the reduction in the in-plane uniformity of the wafer 200 in the radial direction of the rotation of the susceptor 217.

(b) According to the second embodiment, since the reduction in the in-plane uniformity of the wafer 200 may be suppressed by changing only the sizes in directions of the thickness of the dielectric plate 361 at the inner peripheral side in the reaction gas supply region 314 and at the outer peripheral side thereof, the complexity of the device configuration or the like is not caused.

### (Modification of the Second Embodiment)

Also, in the second embodiment, the case in which the thickness of the dielectric plate 361 is small at the inner peripheral side and is gradually increased toward the outer peripheral side is described as an example, but the dielectric plate 361 may be exactly and conversely configured to have the thickness with respect to the above-described case. Even in this case, it is possible to partially adjust the activity of (the radical concentration) of the active species of the reaction gas in the reaction gas supply region 314 to be different at the inner peripheral side from the outer peripheral side.

Also, in the second embodiment, although the case corresponding to the SWP is described, the present invention is not limited thereto. For example, even when the existing plasma generating unit is used (e.g., when plasma is excited by applying power to a parallel plate), the activity of the active species of the reaction gas may be adjusted in each portion of the reaction gas supply region 314 by providing the dielectric plate 361 having the above-described configuration.

### Third Embodiment of the Present Invention

Next, a third embodiment of the present invention will be described with reference to the drawing. However, here, the difference from the above-described first embodiment or second embodiment is mainly described, and description of other points will be omitted.

In the third embodiment, a plasma generating unit is configured differently from that of the first embodiment or the second embodiment.

### (Configuration of the Plasma Generating Unit)

FIG. 16 is an explanatory diagram illustrating an example of a configuration of the plasma generating unit included in the substrate processing apparatus according to the third embodiment. In the third embodiment, a pair of rod-shaped electrodes 371 are provided in the reaction gas supply region 314 as the plasma generating unit. The high frequency power supplied from the high frequency power source 341 is supplied to one of the pair of rod-shaped electrodes 371. Also, the other of the pair of rod-shaped electrodes 371 is electrically grounded.

However, the pair of rod-shaped electrodes 371 are disposed such that a distance L thereof is changed in each portion in the reaction gas supply region 314. Specifically, the pair of rod-shaped electrodes 371 are formed such that the distance L between the pair of rod-shaped electrodes 371 is large at the inner peripheral side in the reaction gas supply region 314, and the distance L is gradually decreased toward the outer peripheral side thereof.

According to the pair of rod-shaped electrodes 371 formed in this manner, the activity of the active species of the reaction gas generated when the high frequency power is supplied is changed according to the size of the distance L. Specifically, as the distance L is increased, the activity of the active species of the reaction gas is reduced, and as the distance L is reduced, the activity of the active species of the reaction gas is increased. Therefore, when the high frequency power is supplied to one of the pair of above-described rod-shaped electrodes 371, the activity of the active species of the reaction gas is reduced at the inner peripheral side in the reaction gas supply region 314, and is increased at the outer peripheral side in the reaction gas supply region 314.

That is, in the third embodiment, since the distance L of the pair of rod-shaped electrodes 371 is changed in each portion of the reaction gas supply region 314, the plasma distribution may be adjusted at the inner peripheral side and the outer peripheral side in the reaction gas supply region 314.

### (Effects According to the Third Embodiment)

According to the third embodiment, one or a plurality of effects to be described below will be obtained.

(a) According to the third embodiment, when the distance L of the pair of rod-shaped electrodes 371 is changed in each portion in the reaction gas supply region 314, the activity (the radical concentration) of the active species of the reaction gas at the inner peripheral side in the reaction gas supply region 314 may be partially adjusted to be different from the activity (the radical concentration) of the active species of the reaction gas at the outer peripheral side thereof. That is, the activity of the active species of the reaction gas supplied onto the wafer 200 may be adjusted according to the distance L of the pair of rod-shaped electrodes 371. Therefore, it is possible to suppress the reduction in the in-plane uniformity of the wafer 200 in a radial direction of the rotation of the susceptor 217.

(b) According to the third embodiment, since the reduction in the in-plane uniformity of the wafer 200 may be suppressed by changing only the distance L of the pair of rod-shaped electrodes 371 at the inner peripheral side in the reaction gas supply region 314 and at the outer peripheral side thereof, the complexity of the device configuration or the like is not caused.

### (Modification of the Third Embodiment)

Also, in the third embodiment, the case in which the distance L of the pair of rod-shaped electrodes 371 is large at the inner peripheral side and is gradually decreased toward the outer peripheral side is described as an example, but it may be contrarily configured thereto. In this case, it is also possible to partially adjust the activity (the radical concentration) of the active species of the reaction gas in the reaction gas supply region 314 to be different at the inner peripheral side from the outer peripheral side.

### Fourth Embodiment of the Present Invention

Next, a fourth embodiment of the present invention will be described with reference to the drawing. However, here, the difference from the above-described first embodiment, second embodiment or third embodiment is mainly described, and description of other points will be omitted.

In the fourth embodiment, a plasma generating unit is configured differently from that of the first embodiment, the second embodiment or the third embodiment.

### (Configuration of the Plasma Generating Unit)

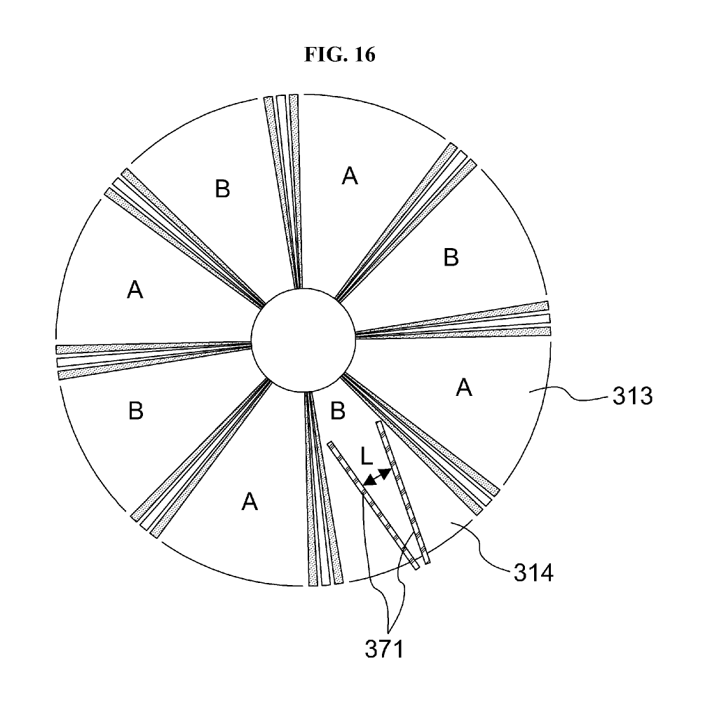

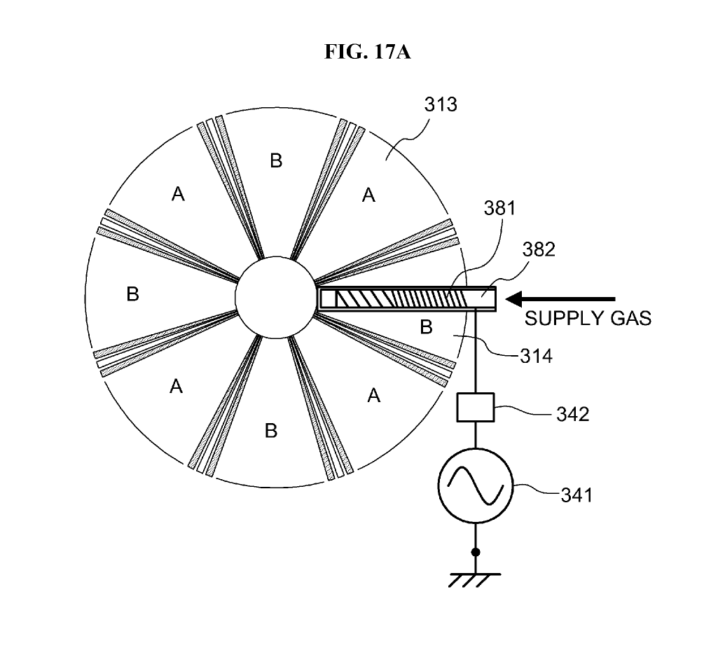

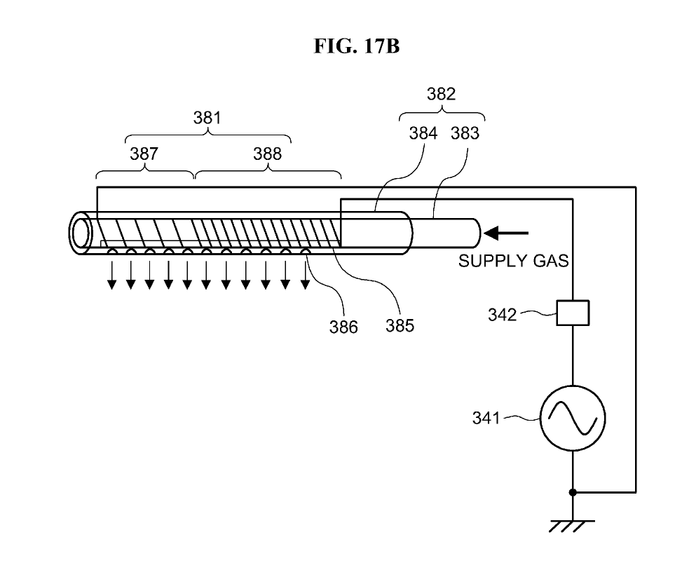

FIGS. 17A and 17B are explanatory diagrams illustrating an example of a configuration of a plasma generating unit included in a substrate processing apparatus according to the fourth embodiment. In the fourth embodiment, as illustrated in FIG. 17A, a gas nozzle 382 having a tubular shape around which a coil 381 is wound is provided in the reaction gas supply region 314 as a plasma generating unit.

The gas nozzle 382 is configured to have a double tube structure including an inner nozzle 383 and an outer nozzle 384 as illustrated in FIG. 17B. The gas nozzle 382 is configured to spray a reaction gas supplied into an inner tube of the inner nozzle 383 into the reaction gas supply region 314 through a slit 385 installed in the inner nozzle 383 and gas supply holes 386 installed in the outer nozzle 384. Also, the gas supply holes 386 are disposed at equal intervals.

The coil 381 is wound around the inner nozzle 383. The coil 381 is connected to the high frequency power source 341 and the matching unit 342, and is configured to serve as an electrode for plasmatizing the reaction gas by supplying high frequency power. Also, the outer nozzle 384 is covered with the coil 381 wound around the inner nozzle 383 in order not to be exposed in the reaction gas supply region 314.

Also, the coil 381 is configured such that the number of windings thereof around the inner nozzle 383 is changed in each of portion of the reaction gas supply region 314. Specifically, a portion 387 in which the number of windings of the coil 381 is large is provided at the inner peripheral side in the reaction gas supply region 314, and a portion 388 in which the number of windings of the coil 381 is small is provided at the outer peripheral side therein.

According to the coil 381 and the gas nozzle 382 formed in this manner, the activity of the active species of the reaction gas generated when the high frequency power is supplied is changed by the density of the number of windings of the coil 381. Specifically, as the number of windings of the coil 381 is small, the activity of the active species of the reaction gas is reduced, and as the number of windings of the coil 381 is large, the activity of the active species of the reaction gas is increased. Therefore, when the reaction gas is supplied onto the gas nozzle 382 while the high frequency power is supplied to the above-described coil 381, the activity of the active species of the reaction gas is reduced at the inner peripheral side in the reaction gas supply region 314, and is increased at the outer peripheral side in the reaction gas supply region 314.

That is, since the coil 381 and the gas nozzle 382 in the fourth embodiment are disposed to have the different number of windings of the coil 381 in each portion of the reaction gas supply region 314, the plasma distribution may be adjusted at the inner peripheral side and the outer peripheral side in the reaction gas supply region 314.

### (Effects According to the Fourth Embodiment)

According to the fourth embodiment, one or a plurality of effects to be described below will be obtained.

(a) According to the fourth embodiment, when the number of windings of the coil 381 wound around the gas nozzle 382 is changed in each portion in the reaction gas supply region 314, the activity (the radical concentration) of the active species of the reaction gas in the reaction gas supply region 314 may be partially adjusted to be different at the inner peripheral side from the outer peripheral side. That is, the activity of the active species of the reaction gas supplied onto the wafer 200 may be adjusted according to the number of windings of the coil 381. Therefore, it is possible to suppress the reduction in the in-plane uniformity of the wafer 200 in a radial direction of the rotation of the susceptor 217.

(b) According to the fourth embodiment, since the reduction in the in-plane uniformity of the wafer 200 may be suppressed by changing only the number of windings of the coil 381 wound around the gas nozzle 382 at the inner peripheral side and the outer peripheral side in the reaction gas supply region 314, the complexity of the device configuration or the like is not caused.

### (Modification of the Fourth Embodiment)

Also, in the fourth embodiment, the case in which the number of windings of the coil 381 is small at the inner peripheral side and is large at the outer peripheral side is described as an example, but it may be contrarily configured thereto. In this case, it is also possible to partially adjust the activity (the radical concentration) of the active species of the reaction gas in the reaction gas supply region 314 to be different at the inner peripheral side from the outer peripheral side.

### Fifth Embodiment of the Present Invention

Next, a fifth embodiment of the present invention will be described with reference to the drawing. However, here, the difference from the above-described first embodiment, second embodiment, third embodiment or fourth embodiment is mainly described, and description of other points will be omitted.

In the fifth embodiment, a substrate processing process is different from that of the first to fourth embodiments.

### (Substrate Processing Process)

In the substrate processing process described in the fifth embodiment, in another substrate processing apparatus (but not illustrated), a silicon nitride (SiN) film serving as a second film (a second silicon-containing film) is formed on the wafer 200 on which a polysilicon (Poly-Si) film serving as a first film (a first silicon-containing film) is formed. The formation of the SiN film is performed, for example, using hexachlorodisilane (HCDS) gas (Si₂Cl₆) serving as a source gas and NH₃ gas serving as a reaction gas. Also, an active species of the reaction gas is generated by plasmatizing by the plasma generating unit having any one configuration described in the first embodiment to the fourth embodiment. In the following description, the plasma generating unit having the configuration described in the first embodiment is used as an example. Also, the first silicon-containing film may be a film having silicon as a main component, and may be an amorphous silicon film, a single crystal silicon film, or a silicon film on which a predetermined element is doped. Here, the predetermined element may be, for example, at least one element of bromine (B), carbon (C), nitrogen (N), aluminum (Al), phosphorus (P) and arsenic (As).

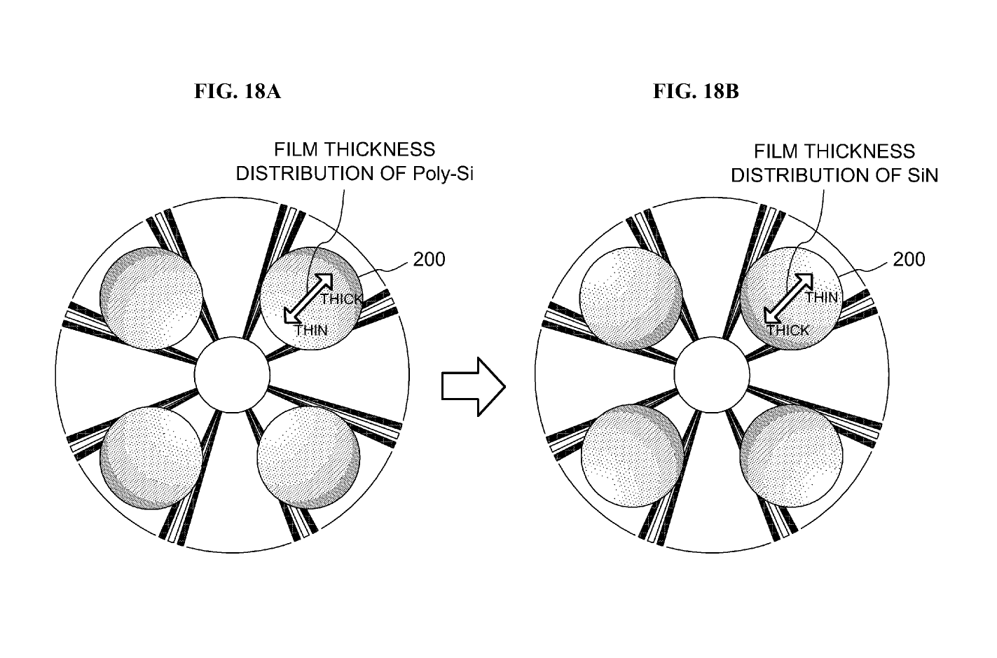

FIGS. 18A and 18B are explanatory diagrams illustrating a specific example of a film forming process performed in the fifth embodiment. Also, four wafers 200 which are processing targets are illustrated in the drawings, but that is a simple example and a different number (e.g., five or more) of wafers may be used.

Here, as illustrated in FIG. 18A, a wafer 200, on which a Poly-Si film is formed such that a film thickness of one portion thereof is large and a film thickness of the other portion thereof is small, is a processing target. When the SiN film is formed on the wafer 200 so as to overlap the Poly-Si film, the substrate processing process is performed in the following order.

When the Poly-Si film is formed on the wafer 200 in the other substrate processing apparatus (but not illustrated), the characteristic of the Poly-Si film is measured using a measuring device (not illustrated) with respect to the wafer 200. Specifically, for example, a film thickness distribution, a film quality (crystallinity) distribution, a film stress distribution, a film composition distribution, a dielectric constant distribution, a resistance distribution, an unevenness dimension and the like of the Poly-Si film are measured. Since the measurement thereof is well known, detailed description thereof is omitted herein. Information (hereinafter, referred to as simply “characteristic information”) on the measured characteristic of the Poly-Si film is input to the controller 221 of the other substrate processing apparatus 100, which performs the formation of a SiN film. The input of the characteristic information to the controller 221 may be manually performed or may be performed using a network or an external recording medium.

When the characteristic information is input, the controller 221 commands an instruction to the notch aligning device 106 based on the characteristic information such that the detection of a direction of the wafer 200 and the correction of the corresponding direction are performed. Also, the controller 221 commands an instruction to the vacuum transfer robot 112 so as to load the wafer 200 into the process chamber 202a in a direction after correction by the notch aligning device 106. When the wafer 200 is load into the process chamber 202a in this manner, the film forming process of the SiN film starts to be performed on the loaded wafer 200 in the process chamber 202a.

In this case, the plasma generating unit adjusts a power supply amount to the plate electrode 351 such that a combined film thickness distribution of the Poly-Si film and the SiN film is flat. Specifically, as illustrated in FIG. 18B, based on the characteristic information input to the controller 221 and a result of the position alignment in the notch aligning device 106, the SiN film is formed on a surface of the wafer 200 on which the Poly-Si film is formed while the power supply amount to the plate electrode 351 is adjusted such that a film thickness of one side thereof is small, and a film thickness of the other side thereof is large in an opposite manner to the Poly-Si film.

The wafer 200 on which the Poly-Si film is formed by overlapping the Poly-Si film in this manner is unloaded from the process chamber 202a, and stored in the pod 109.

According to the above-described substrate processing process, when the SiN film is formed on the surface of the wafer 200 on which the Poly-Si film is formed, the tuning in which the combined film thickness distribution of the Poly-Si film and the SiN film is flat may be performed by adjusting the plasma distribution at the inner peripheral side and the outer peripheral side in the reaction gas supply region 314. That is, the plasma distribution in the reaction gas supply region 314 may be adjusted to be partially changed in the reaction gas supply region 314 according to the wafer 200 which is the processing target.

### (Effects According to the Fifth Embodiment)

According to a fifth embodiment, one or a plurality of effects to be described below will be obtained.

(a) According to the fifth embodiment, the plasma distribution is partially adjusted at the inner peripheral side and the outer peripheral side in the reaction gas supply region 314 when the reaction gas is plasmatized, and thus it is possible to suppress the reduction in the in-plane uniformity such as the film thickness, the film quality or the like of the film formed on the wafer 200.

(b) According to the fifth embodiment, when the plasma distribution is partially adjusted in the reaction gas supply region 314 according to the wafer 200 which is the processing target, it is possible for the combined film thickness distribution of each film to be flat when a new film is formed, for example, on the surface of the wafer 200 on which the formed film is present. That is, in this case, the reduction in the in-plane uniformity on the wafer 200 may also be suppressed.

### Other Embodiments of the Present Invention

The first to fifth embodiments of the present invention have been specifically described above. The present invention is not limited to the above-described embodiments, but may be variously changed without departing from the scope of the invention.

### (Gas Type)

Also, for example, in the above-described embodiments, in the film forming process performed by the substrate processing apparatus, the case in which a TiN film is formed on the wafer 200 when TiCl₄ gas is used as the source gas (a first process gas), NH₃ gas is used as the reaction gas (a second process gas), and the gases are alternately supplied is described as an example, but the present invention is not limited thereto. That is, the processing gas used in the film forming process is not limited to TiCl₄ gas, NH₃ gas or the like, but a different type of thin film may be formed using a different type of gas. Also, even when three or more types of processing gases are used, the present invention may be applied to any process as long as the film forming process is performed by alternately supplying the processing gases.

### (Number of Divisions of the Processing Region)

In the above-described embodiments, the case in which two or more of the source gas supply regions 313 and the reaction gas supply region 314 are provided as the regions 313 through 315 of the gas supply plate 310 and the inert gas supply region 315 interposed between the source gas supply region 313 and the reaction gas supply region 314 is provided is described as an example, but the present invention is not limited thereto. That is, the present invention may be applied to any substrate processing apparatus as long as a processing space is divided into a plurality of processing regions.

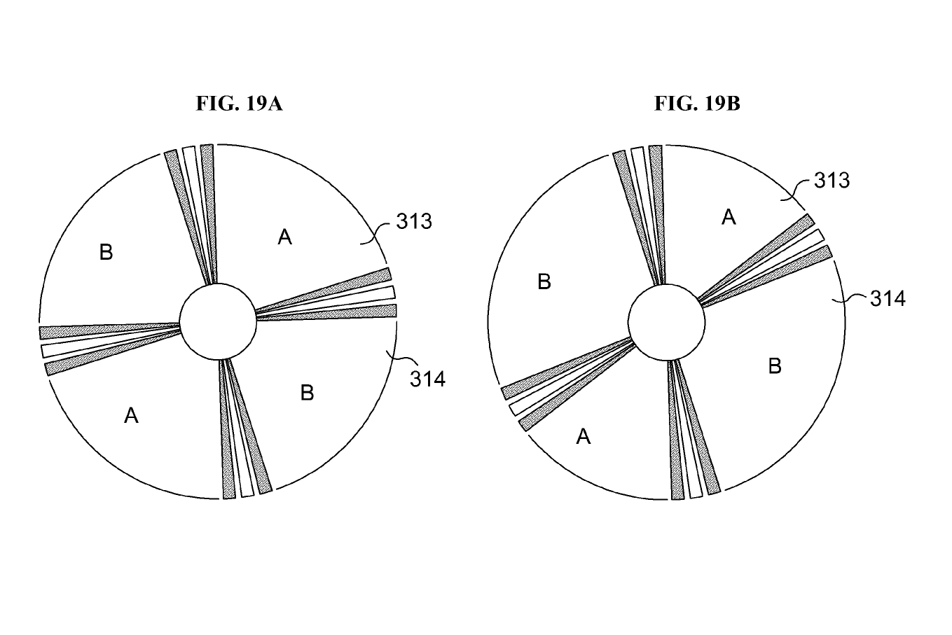

FIGS. 19A and 19B are explanatory diagrams illustrating examples of a division form of a processing region in a substrate processing apparatus according to another embodiment of the present invention. Also, in order to facilitate understanding, the case in which a gas supply plate 310 includes two source gas supply regions 313 (mark A in the drawing) and two reaction gas supply regions 314 (mark B in the drawing) is illustrated in the drawings.

In the example illustrated in FIG. 19A, the gas supply regions 313 and 314 are divided such that the source gas supply region 313 (the mark A in the drawing) and the reaction gas supply region 314 (the mark B in the drawing) have the same area. In the gas supply plate 310 having such a configuration, times through which the wafer 200 passes through the source gas supply region 313 and the reaction gas supply region 314, that is, times to which the wafer 200 is exposed to the source gas and the reaction gas are substantially the same. However, according to the types of the thin film that should be formed on the wafer 200, the times to which the wafer 200 is exposed to the source gas and the reaction gas do not necessarily have to be substantially the same, and a case where the times are different from each other may be appropriate. For example, in the example illustrated in FIG. 19B, the gas supply regions 313 and 314 are divided such that the area of the reaction gas supply region 314 (mark B in the drawing) is greater than the area of the source gas supply region 313 (mark A in the drawing). In the gas supply plate 310 having such a configuration, when the supply amount of the reaction gas onto the wafer 200 is greater than that of the source gas, the reaction amount of each of the gases may be increased. Also, on the contrary, it may be appropriate when the area of the reaction gas supply region 314 (the mark B in the drawing) is smaller than the area of the source gas supply region 313 (the mark A in the drawing).

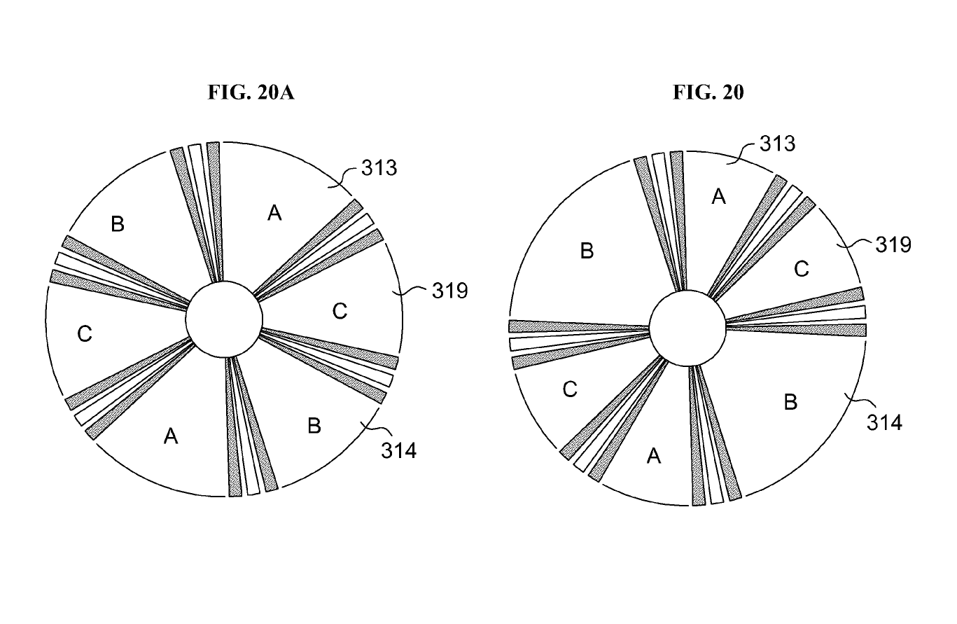

FIGS. 20A and 20B are explanatory diagrams illustrating examples of a division form of a processing region in a substrate processing apparatus according to still another embodiment of the present invention. The case in which the first source gas supply region 313 in which a first source gas is supplied onto the wafer 200 and the second source gas supply region 319 in which a second source gas different from the first source gas is supplied onto the wafer 200 are provided as source gas supply regions is illustrated in the drawings. As the first source gas, for example, TiCl₄ gas is used the same as the above-described embodiments. Also, as the second source gas, for example, trimethyl aluminum (TMA) gas is used. Also, the reaction gas (NH₃ gas) and the inert gas (N₂ gas) are used the same as the above-described embodiments. When these types of gases are supplied onto the wafer 200, it is possible to form a thin film of titanium aluminum nitride (TiAlN) which is a ternary alloy on the wafer 200.

In the example illustrated in FIG. 20A, the gas supply regions 313, 314 and 319 are divided such that the first source gas supply region 313 (mark A in the drawing), the reaction gas supply region 314 (mark B in the drawing) and the second source gas supply region 319 (mark C in the drawing) have the same area. In the gas supply plate 310 having such a configuration, times through which the wafer 200 passes through the first source gas supply region 313, the second source gas supply region 319 and the reaction gas supply region 314, that is, times to which the wafer 200 is exposed to the first source gas, the second source gas and the reaction gas are substantially the same. On the other hand, in the example illustrated in FIG. 20B, the gas supply regions 313, 314 and 319 are divided such that the area of the reaction gas supply region 314 (mark B in the drawing) is greater than the area of each of the first source gas supply region 313 (mark A in the drawing) and the second source gas supply region 319 (mark C in the drawing). In the gas supply plate 310 having such a configuration, when the supply amount of the reaction gas onto the wafer 200 is greater than the supply amount of each of the first source gas and the second source gas, the reaction amount of each of the gases may be increased.

Also, although it is not illustrated as the division form of the processing region, in addition to the source gas supply region, a first reaction gas supply region and a second reaction gas supply region may be provided. Specifically, for example, HCDS gas is used as a source gas, NH₃ gas is used as a first reaction gas, and oxygen gas (O₂ gas) is used as second reaction gas. When these types of gases are supplied onto the wafer 200, it is possible to form a thin film of SiON on the wafer 200.

Also, the gas supply regions 313, 314 and 319 may be configured to form a multi-element thin film such as SiOCN by adding a region into which a carbon source gas is supplied.

### (Relative Position Movement)

In the above-described embodiments, the case in which the relative position of the wafer 200 placed on the susceptor 217 and the cartridge head 300 is moved by rotating the susceptor 217 or the cartridge head 300 is described as an example, but the present invention is not limited thereto. That is, when the relative position of the wafer 200 placed on the susceptor 217 and the cartridge head 300 is moved, it is not necessary to apply a rotary drive type described in the embodiments to the present invention, and it is possible to apply a direct drive type for example, using a conveyor or the like thereto.

### (Others)

In the above-described embodiments, the film forming process is described as an example of a process processing performed by the substrate processing apparatus, but the present invention is not limited thereto. That is, any process processing as long as the substrate can sequentially pass through the plurality of processing regions, such as processing in which an oxide film and a nitride film are formed and processing in which a film including a metal is formed rather than the film forming process, may be provided. Also, regardless of the detailed contents of the substrate processing, in addition to the film forming process, the present invention may be preferably applied to other substrate processing such as annealing processing, oxidizing, nitriding, diffusion processing, lithography processing and the like. Also, the present invention may be preferably applied to other substrate processing apparatus such as an annealing processing apparatus, an oxidation apparatus, a nitriding apparatus, an exposure apparatus, a coating apparatus, a drying apparatus, a heating apparatus, a processing apparatus using plasma and the like. Also, in the present invention, these apparatuses may be mixed. Also, it is possible to replace a part of the configuration of an embodiment with the configuration of another embodiment, and it is also possible to add the configuration of another embodiment to the configuration of an embodiment. Also, it is possible to add, remove and replace the configuration of another embodiment to, from and with a part of the configuration of each embodiment.

According to the present invention, a plasma distribution of a processing region may be partially adjusted, and thus a reduction in in-plane uniformity of a film formed on a substrate can be suppressed.

### Preferred Embodiments of the Present Invention

Hereinafter, preferred embodiments according to the present invention are supplementarily noted.

### Supplementary Note 1

According to an aspect of the present invention, there is provided a substrate processing apparatus including: a substrate support configured to support a substrate; a dividing structure defining a processing region in a space facing the substrate support; a gas supply unit configured to supply a processing gas into the processing region; and a plasma generating unit configured to generate an active species by plasmatizing the processing gas supplied into the processing region by the gas supply unit, and to control an activity of the active species independently for each portion of the processing region when plasmatizing the processing gas.

### Supplementary Note 2

In the substrate processing apparatus of Supplementary note 1, preferably, the substrate support includes a substrate placement surface where a plurality of substrates arranged along a circumference thereof, the processing region has a sector shape, and the plasma generating unit is configured to control the activity of the active species independently for center and peripheral portions of the sector shape.

### Supplementary Note 3

In the substrate processing apparatus of any one of Supplementary notes 1 and 2, preferably, the plasma generating unit includes: a high frequency power supply unit installed in each portion of the processing region; and an impedance adjusting unit installed in each portion of the processing region to correspond to the high frequency power supply unit.

### Supplementary Note 4

In the substrate processing apparatus of Supplementary note 3, preferably, the high frequency power supply unit includes a plate electrode facing the substrate placement surface.

### Supplementary Note 5

In the substrate processing apparatus of Supplementary note 4, preferably, wherein the plasma generating unit further includes a ground electrode disposed between the plate electrode and the substrate placement surface.

### Supplementary Note 6

In the substrate processing apparatus of Supplementary note 4, preferably, the substrate support serves as a ground electrode.

### Supplementary Note 7

In the substrate processing apparatus of Supplementary note 4, preferably, the plasma generating unit further includes a ground electrode disposed on a same plane as the plate electrode without overlapping the plate electrode.

### Supplementary Note 8

In the substrate processing apparatus of any one of Supplementary notes 1 through 7, preferably, the plasma generating unit includes a dielectric plate disposed in the processing region where a distance between the dielectric plate and the substrate varies for each portion of the processing region.

### Supplementary Note 9

In the substrate processing apparatus of Supplementary note 8, preferably, a microwave is supplied to the dielectric plate.

### Supplementary Note 10

In the substrate processing apparatus of any one of Supplementary notes 1 and 2, preferably, the plasma generating unit further includes a pair of electrodes space apart, and a distance between the pair of electrodes varies for each portion of the processing region.

### Supplementary Note 11

In the substrate processing apparatus of any one of Supplementary notes 1 and 2, preferably, the plasma generating unit includes an electrode configured such that the number of windings of a coil around a gas nozzle is changed in each portion of the processing region as an electrode including the coil which winds the vicinity of the gas nozzle having a tubular shape disposed in the processing region.

### Supplementary Note 12

According to another aspect of the present invention, there is provided a plasma generator configured to generate an active species by plasmatizing a processing gas supplied into a processing region, the plasma generator including: an electrode structure configured to control an activity of the active species independently for each portion of the processing region when plasmatizing the processing gas.

### Supplementary Note 13

According to still another aspect of the present invention, there is provided a method of manufacturing a semiconductor device including: (a) placing a substrate on a substrate support; (b) supplying a process gas into a processing region formed in a space facing the substrate support; and (c) generating an active species by plasmatizing the processing gas supplied into the processing region wherein an activity of the active species is controlled independently for each portion of the processing region.

### Supplementary Note 14

According to still another aspect of the present invention, there is provided a program for causing a computer to control a substrate processing apparatus to perform: (a) placing a substrate on a substrate support; (b) supplying a process gas into a processing region formed in a space facing the substrate support; and (c) generating an active species by plasmatizing the processing gas supplied into the processing region wherein an activity of the active species is controlled independently for each portion of the processing region.

### Supplementary Note 15

According to still another aspect of the present invention, there is provided a non-transitory computer-readable recording medium storing a program for causing a computer to control a substrate processing apparatus to perform: (a) placing a substrate on a substrate support; (b) supplying a process gas into a processing region formed in a space facing the substrate support; and (c) generating an active species by plasmatizing the processing gas supplied into the processing region wherein an activity of the active species is controlled independently for each portion of the processing region.

What is claimed is:

1. A substrate processing apparatus comprising:
a substrate support configured to support a substrate;
a dividing structure defining a processing region in a space facing the substrate support;
a gas supply unit configured to supply a processing gas into the processing region; and
a plasma generating unit configured to generate an active species by plasmatizing the processing gas supplied into the processing region by the gas supply unit, and to control an activity of the active species independently for each portion of the processing region when plasmatizing the processing gas.

2. The substrate processing apparatus of claim 1, wherein the substrate support comprises a substrate placement surface where a plurality of substrates arranged along a circumference thereof, the processing region has a sector shape, and the plasma generating unit is configured to control the activity of the active species independently for center and peripheral portions of the sector shape.

3. The substrate processing apparatus of claim 1, wherein the plasma generating unit comprises: a high frequency power supply unit installed in each portion of the processing region; and an impedance adjusting unit installed in each portion of the processing region to correspond to the high frequency power supply unit.

4. The substrate processing apparatus of claim 2, wherein the plasma generating unit comprises: a high frequency power supply unit installed in each portion of the processing region; and an impedance adjusting unit installed in each portion of the processing region to correspond to the high frequency power supply unit.

5. The substrate processing apparatus of claim 3, wherein the high frequency power supply unit comprises a plate electrode facing the substrate placement surface.

6. The substrate processing apparatus of claim 5, wherein the plasma generating unit further comprises a ground electrode disposed between the plate electrode and the substrate placement surface.

7. The substrate processing apparatus of claim 5, wherein the substrate support is connected to ground potential.

8. The substrate processing apparatus of claim 5, wherein the plasma generating unit further comprises a ground electrode disposed on a same plane as the plate electrode without overlapping the plate electrode.

9. The substrate processing apparatus of claim 1, wherein the plasma generating unit comprises a dielectric plate disposed in the processing region where a distance between the dielectric plate and the substrate varies for each portion of the processing region.

10. The substrate processing apparatus of claim 5, wherein the plasma generating unit further comprises a dielectric plate disposed in the processing region where a distance between the dielectric plate and the substrate varies for each portion of the processing region.

11. The substrate processing apparatus of claim 9, wherein a microwave is supplied to the dielectric plate.

12. The substrate processing apparatus of claim 1, wherein the plasma generating unit further comprises a pair of electrodes space apart, and a distance between the pair of electrodes varies for each portion of the processing region.

13. The substrate processing apparatus of claim 2, wherein the plasma generating unit further comprises a pair of electrodes space apart, and a distance between the pair of electrodes varies for each portion of the processing region.
